(19) United States
(12) Patent Application Publication
(10) Pub. No.: US 2026/0136631 A1
(43) Pub. Date: May 14, 2026

(54) PASSIVATION LAYER AND BARRIER LAYER IN GATE STRUCTURES

(71) Applicant: Taiwan Semiconductor Manufacturing Company, Ltd., Hsin-Chu (TW)

(72) Inventors: Cheng-Ming Lin, Kaohsiung City (TW); Tsung-Kai Chiu, Hsinchu County (TW); Wei-Yen Woon, Taoyuan City (TW); Szuya Liao, Zhubei (TW); Kai-Chieh Yang, New Taipei City (TW)

(21) Appl. No.: 19/079,683

(22) Filed: Mar. 14, 2025

Related U.S. Application Data
(60) Provisional application No. 63/720,046, filed on Nov. 13, 2024.

(51) Int. Cl. H10D 64/27; H01L 21/28; H10D 30/00; H10D 30/01; H10D 62/10; H10D 84/01; H10D 84/85

(52) U.S. Cl. CPC H10D 64/514; H10D 62/115; H10D 64/01304; H10D 64/01354; H10D 64/518; H10D 30/0191; H10D 30/502; H10D 62/121; H10D 64/513; H10D 84/0172; H10D 84/85

(57) ABSTRACT

A method includes providing a structure. The structure includes a stack of bottom channel layers, a stack of top channel layers disposed over the stack of bottom channel layers, an isolation feature sandwiched by the stack of bottom channel layers and the stack of bottom channel layers, and a first work function metal (WFM) layer wrapping around each of the bottom channel layers. The method further includes forming a second WFM layer wrapping around each of the top channel layers, forming a passivation layer on the second WFM layer by performing a gas treatment to the structure, and forming a metal fill layer over the passivation layer.

### PRIORITY DATA

This application claims priority to U.S. Provisional Application Ser. No. 63/720,046, filed Nov. 13, 2024, the entirety of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, stacked device structures are introduced to enable further density reduction for advanced IC technology nodes. For example, stacked transistors can provide a complementary field effect transistor (CFET). However, fabrication of such stacked device structures introduces more challenges. As a result, existing implementations have not been satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor structure, according to one or more aspects of the present disclosure.

FIG. 2 illustrates a fragmentary top view of an exemplary semiconductor structure during various fabrication stages in the method of FIG. 1, according to one or more aspects of the present disclosure.

FIGS. 2, 3, 4, 5, 6, 7, 8, 9, 10A, 10B, and 11 illustrate fragmentary cross-sectional views of an exemplary semiconductor structure during various fabrication stages in the method of FIG. 1, according to one or more aspects of the present disclosure.

FIG. 12 illustrates a flowchart of a method for forming a semiconductor structure, according to one or more aspects of the present disclosure.

FIGS. 13A, 13B, and 14 illustrate fragmentary cross-sectional views of an exemplary semiconductor structure during various fabrication stages in the method of FIG. 12, according to one or more aspects of the present disclosure.

FIGS. 15A, 15B, and 15C illustrate fragmentary schematic cross-sectional views of alternative semiconductor structures fabricated by the method of FIG. 1 or the method of FIG. 12, according to one or more aspects of the present disclosure.

FIG. 16 illustrates a flowchart of a method for forming a semiconductor structure, according to one or more aspects of the present disclosure.

FIGS. 17, 18, 19, 20, 21, 22, 23A, 23B, 24, 25, 26, 27, 28, 29A, 29B, 30, 31A, and 31B illustrate fragmentary cross-sectional views of an exemplary semiconductor structure during various fabrication stages in the method of FIG. 16, according to one or more aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Stacked transistor structures can provide further density reduction for advanced integrated circuit (IC) technology nodes (particularly as they advance to 3 nm (N3) and below), especially when the stacked transistor structures include multigate devices, such as fin-like field effect transistors (FinFETs), gate-all-around (GAA) transistors including nanowires and/or nanosheets, other types of multigate devices, etc. Stacked transistor structures include vertically stacked transistors. For example, a stacked transistor structure can include a first transistor (i.e., an upper/top transistor) disposed over a second transistor (i.e., a lower/bottom transistor). The transistor stack can provide a complementary field effect transistor (CFET) when the first transistor and the second transistor are of opposite conductivity type (i.e., an n-type transistor and a p-type transistor). In ultra-scaled devices, it may allow only work function metal deposited inside gate region due to gate pitch (spacing) limit. Metal oxidation and undesired diffusions (e.g., metal diffusion) of the work function metal may cause threshold voltage (Vt) shift and may impact performance of the devices.

The present disclosure is generally related to stacked transistor structures having a passivation layer and/or a barrier layer and methods of forming same. In an example process, a structure (e.g., a CFET precursor) is provided. The structure includes a stack of bottom channel layers disposed over a substrate and a stack of top channel layers disposed over the stack of bottom channel layers. The stack of top channel layers and the stack of bottom channel layers are separated by a middle insulation structure. In some embodiments, the structure includes a first type work function metal (WFM) layer wrapping around the stack of bottom channel layers and a second type WFM layer wrapping around the stack of top channel layers. A gas treatment may be performed to the structure, thereby forming a passivation layer over the second type WFM layer. The passivation layer may include silicon, carbon, or a combination thereof. An adhesion layer and a metal fill layer may be deposited over the passivation layer. By having the passivation layer, oxygen diffusion into the second type WFM layer may be mitigated, thus threshold voltage (Vt) control of the second type WFM layer may be improved. In some other embodiments, a barrier layer is formed between the first type WFM layer and the second type WFM layer by performing a gas treatment. The barrier layer may have a similar composition and thickness as the passivation layer. By having the barrier layer, metal diffusion between the first type WFM layer and the second type WFM layer may be mitigated, and Vt control of the first type WFM layer may be improved. The embodiments described above may be combined, for example, a structure may include both the barrier layer and the passivation layer and have benefits from both of them.

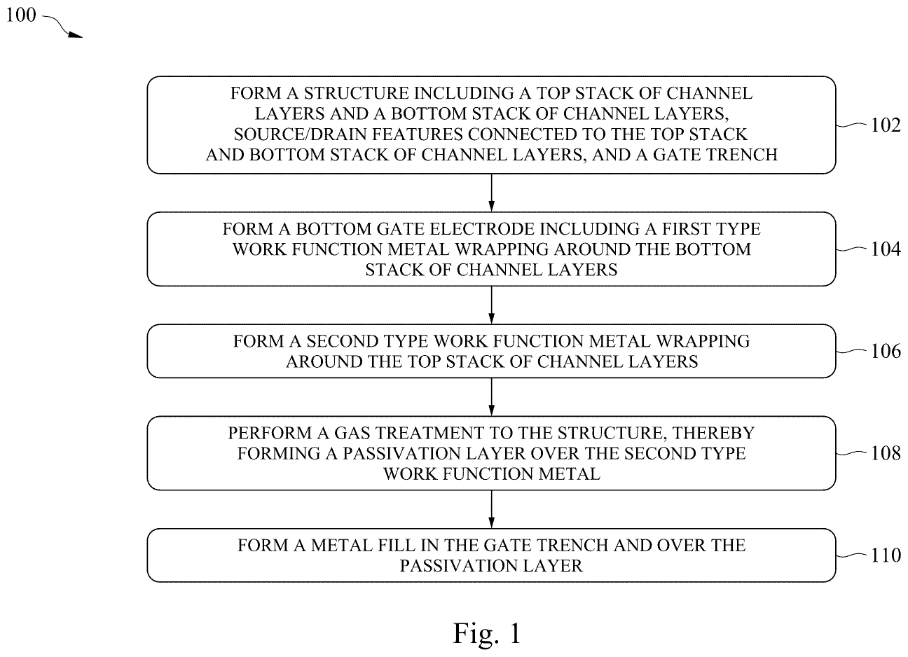

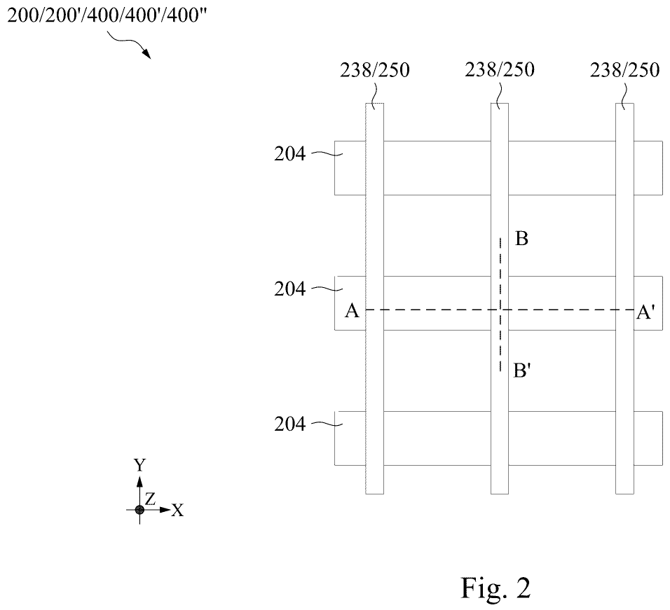

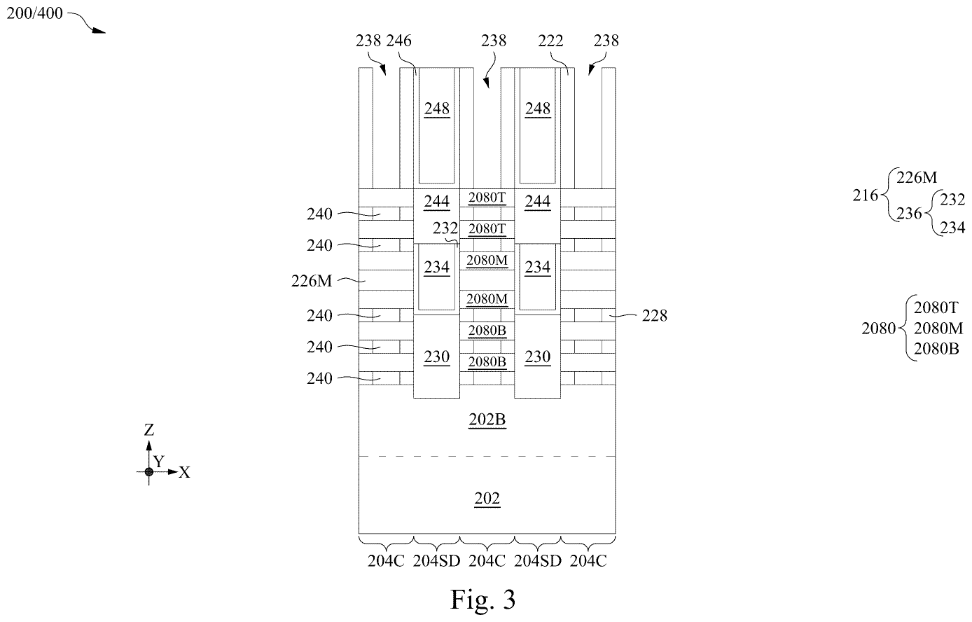

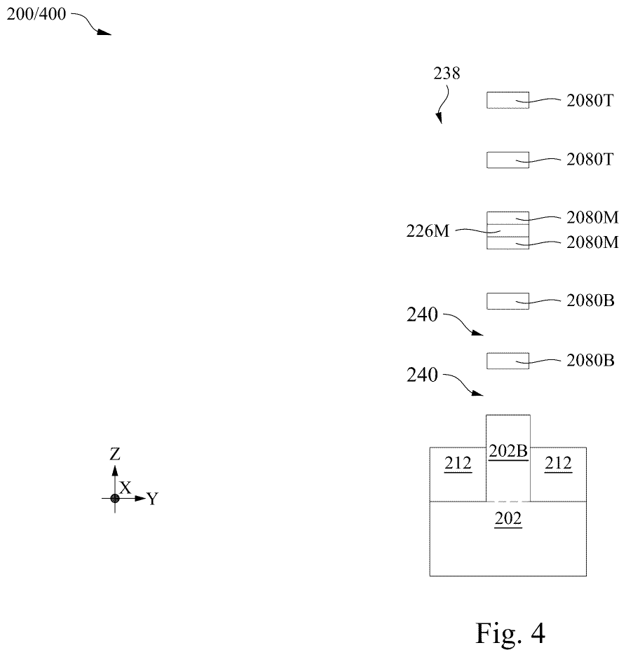

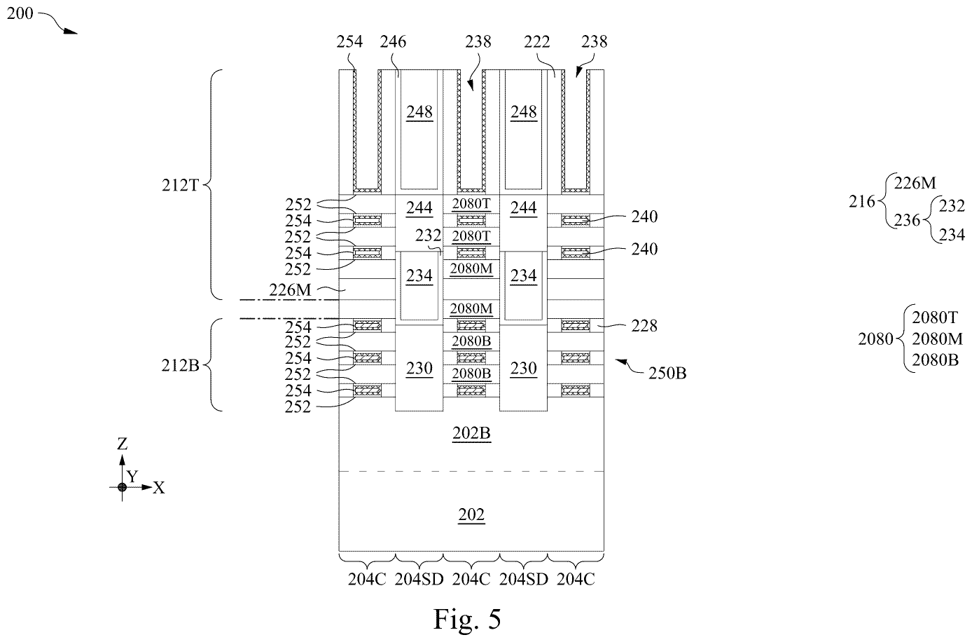

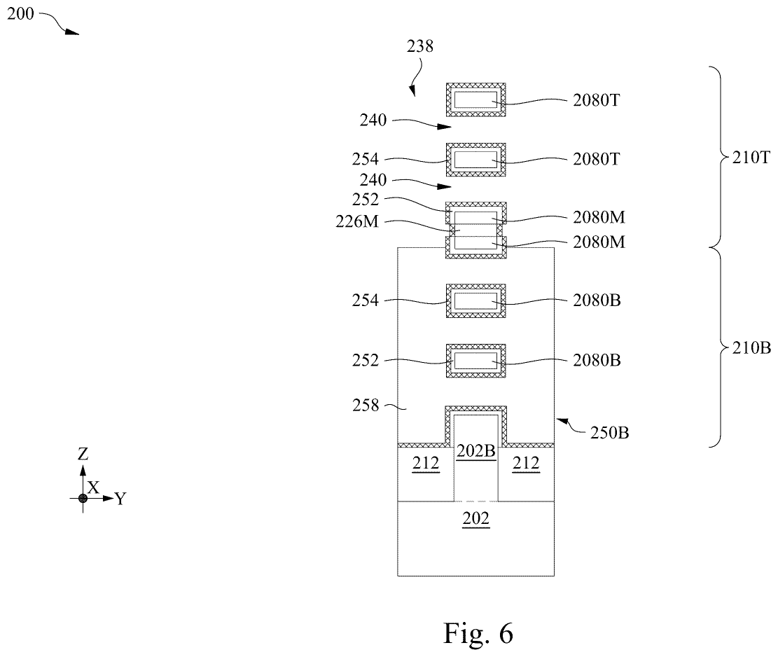

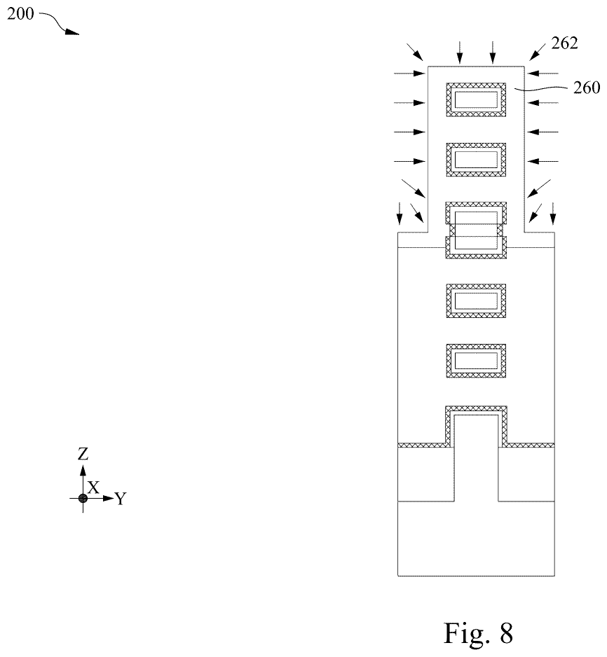

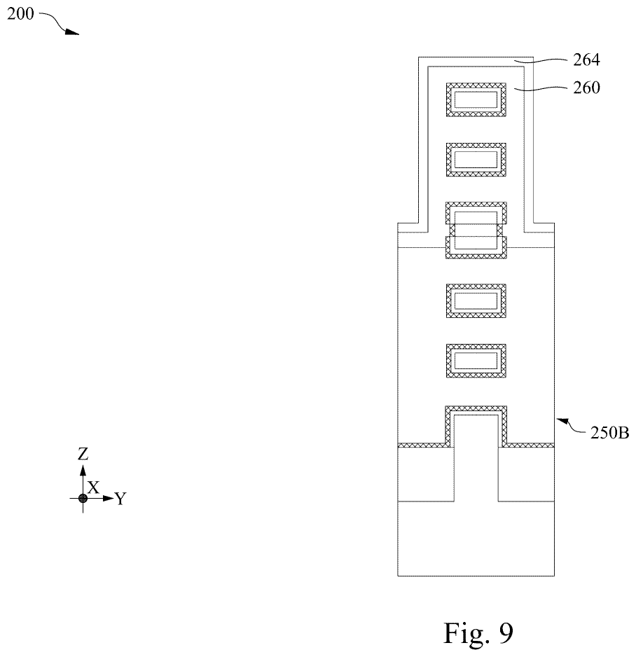

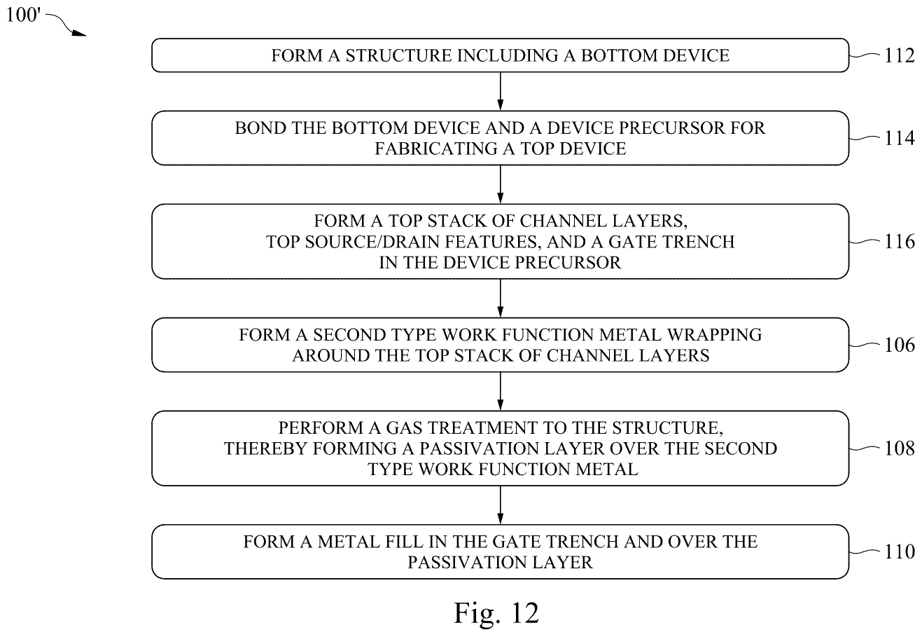

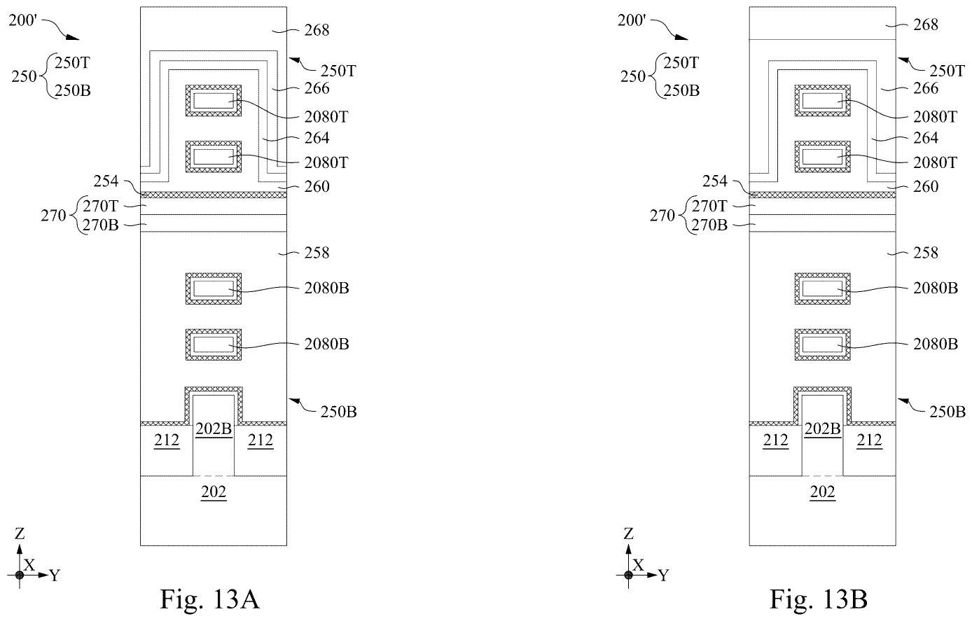

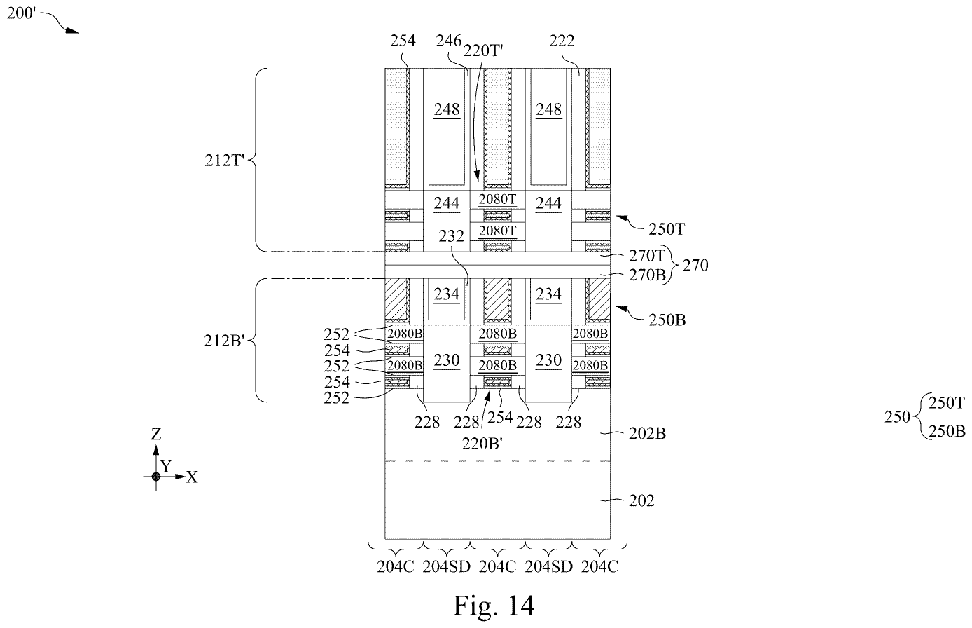

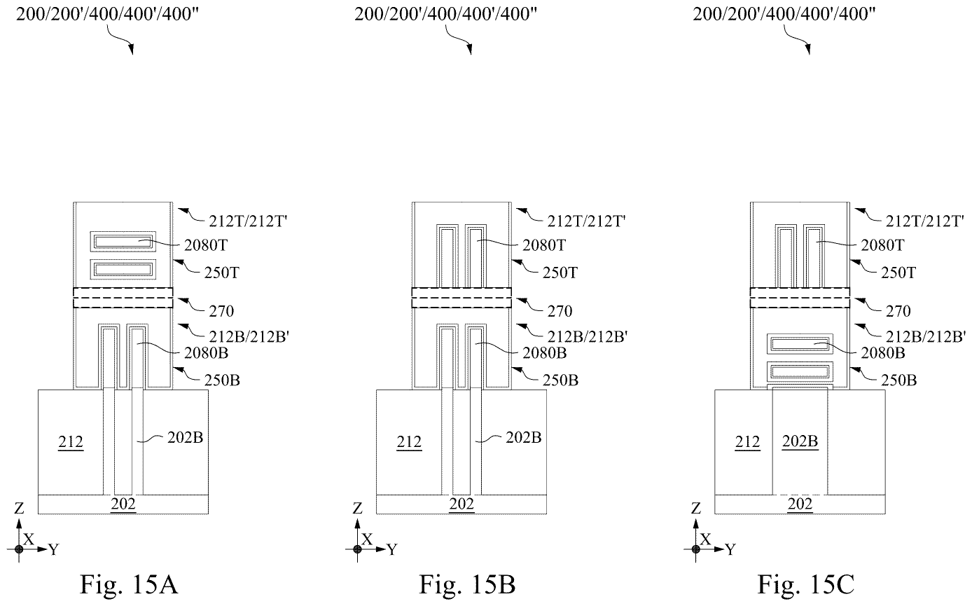

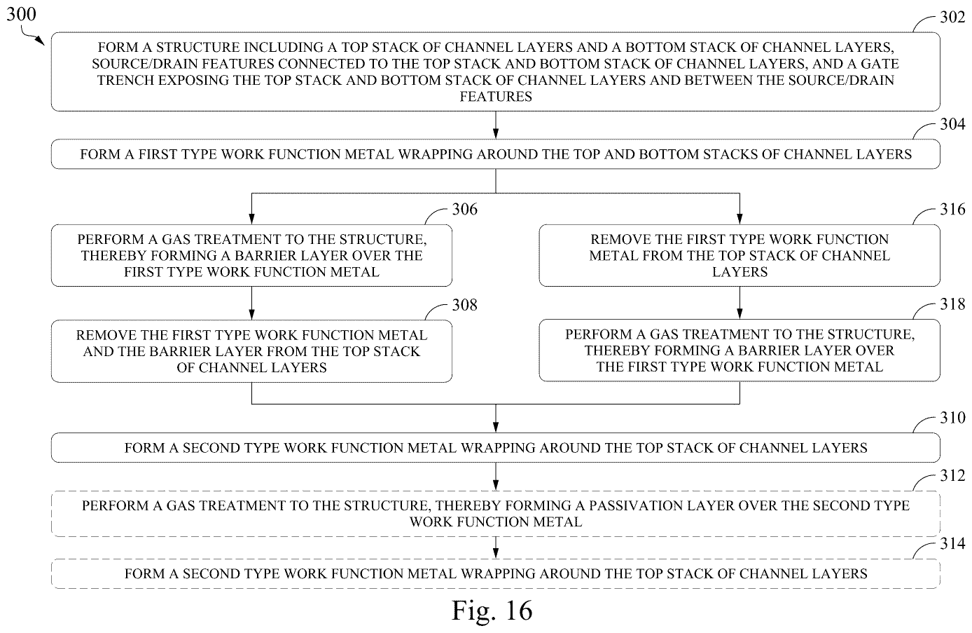

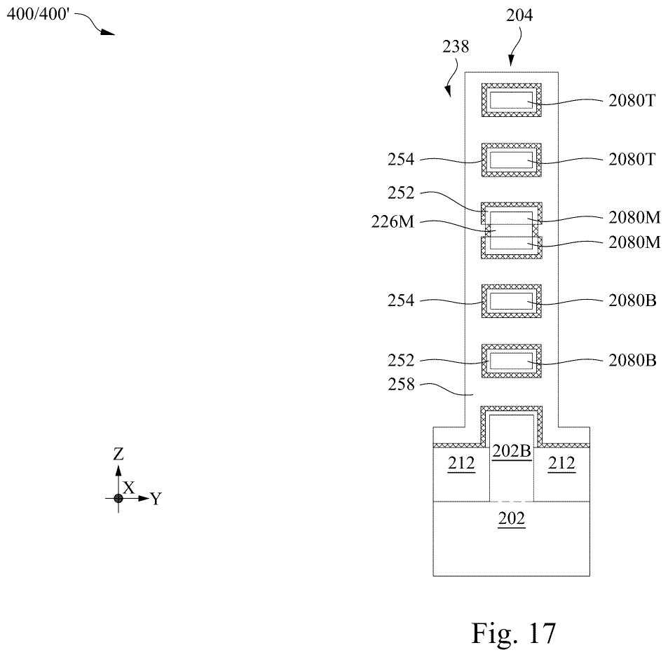

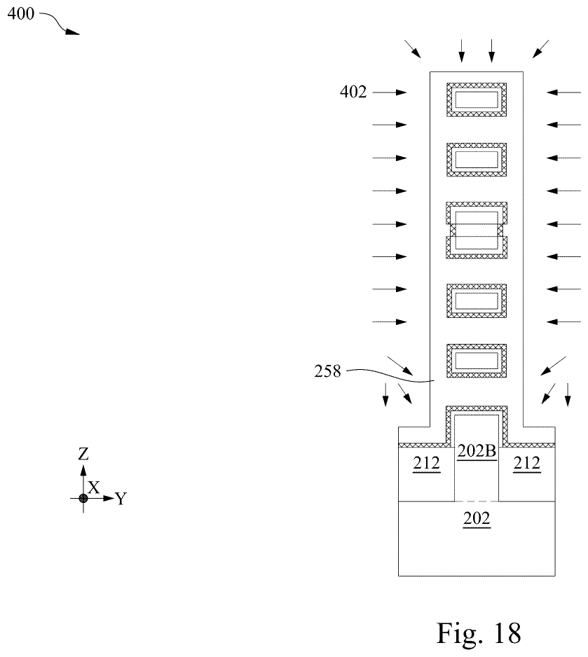

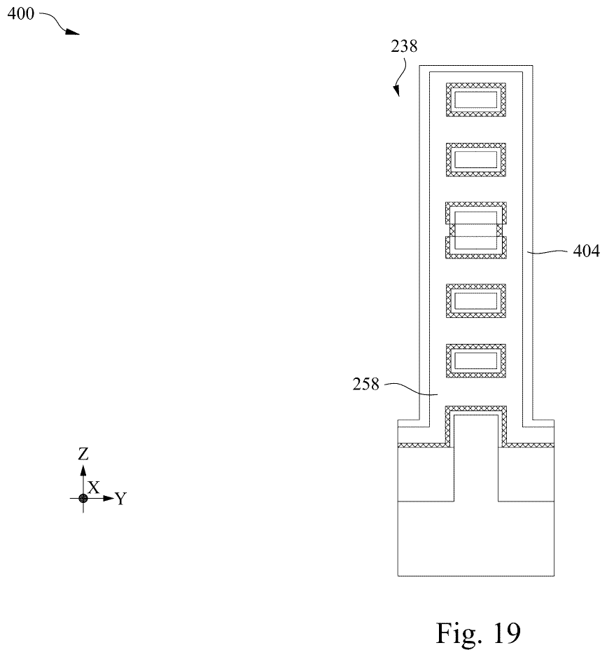

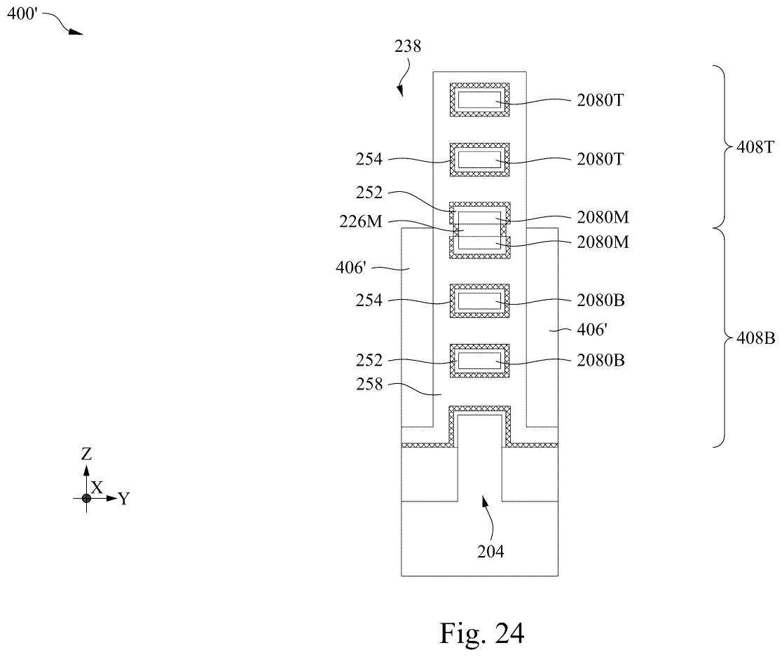

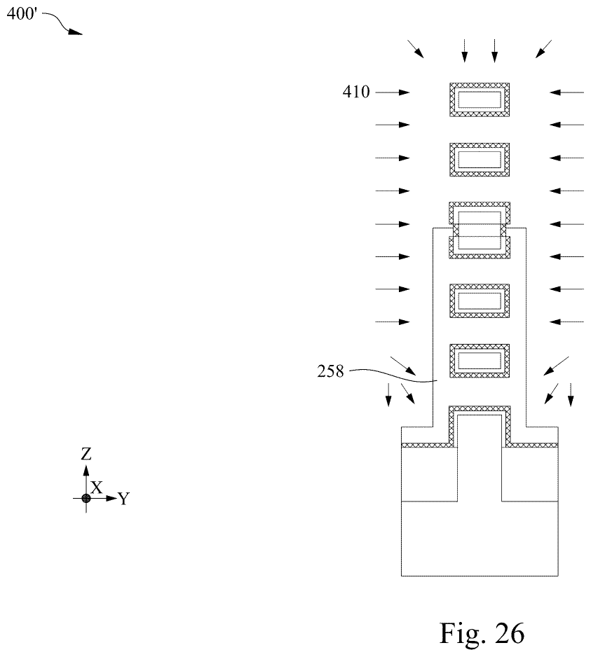

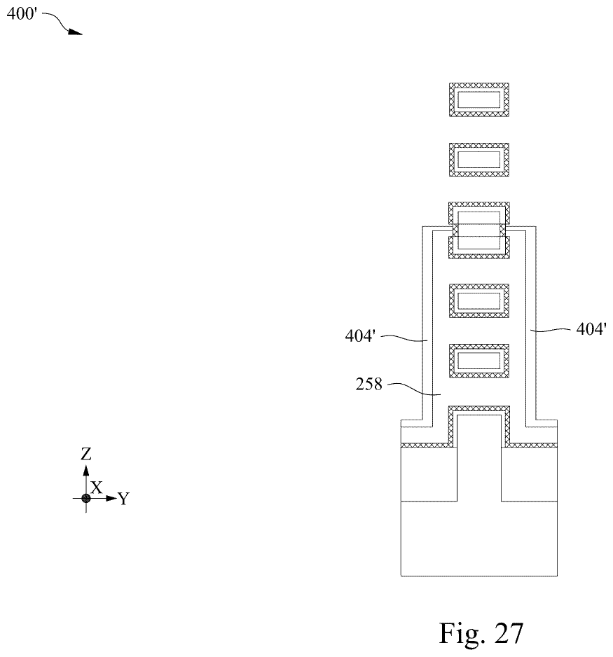

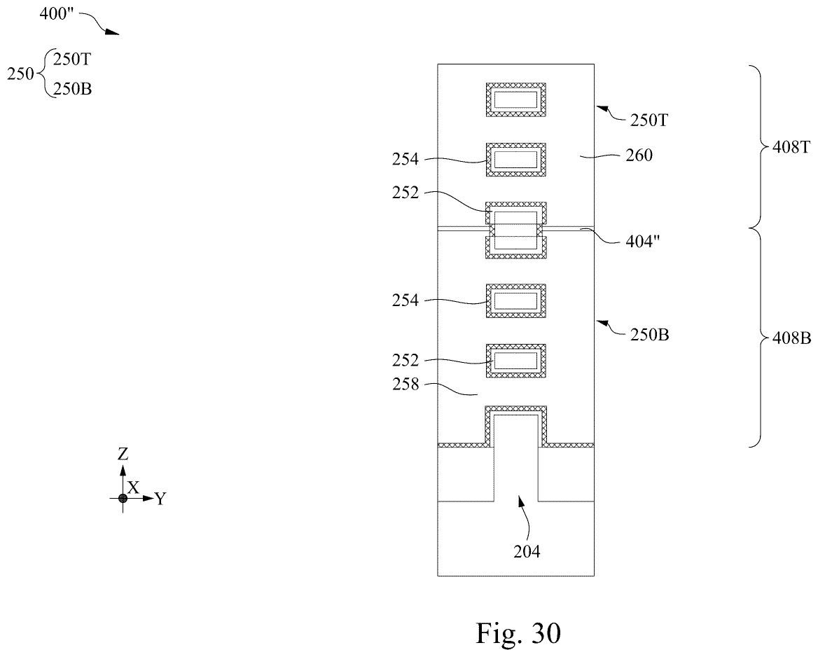

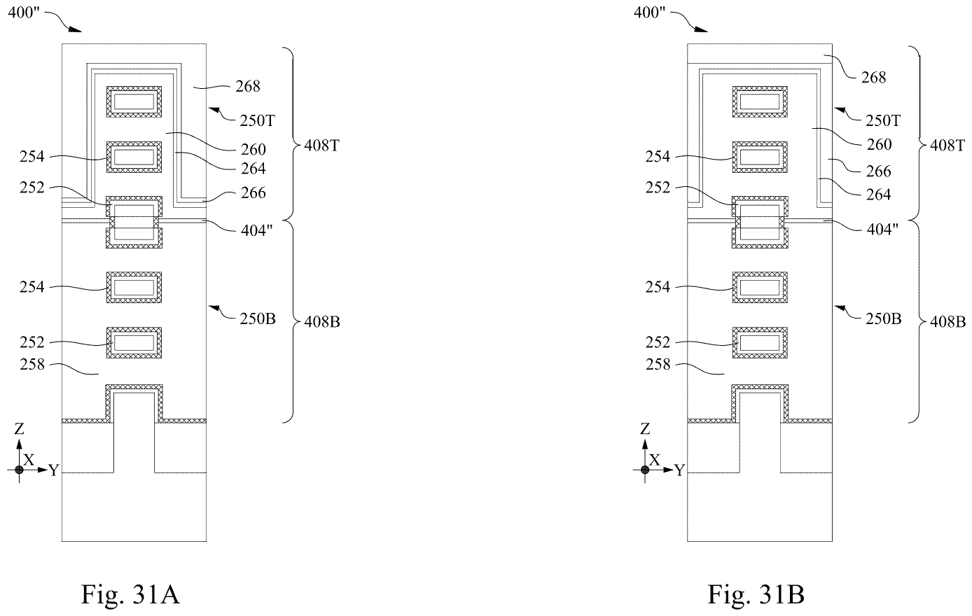

The various aspects of the present disclosure will now be described in more detail with reference to the figures. In that regard, FIG. 1 is a flowchart illustrating method 100 of forming a semiconductor structure according to embodiments of the present disclosure. Method 100 is described below in conjunction with FIGS. 2-11, which are fragmentary top or cross-sectional views of a structure 200 at different stages of fabrication according to embodiments of method 100 in FIG. 1. FIG. 12 is a flowchart illustrating method 100′ of forming a semiconductor structure according to embodiments of the present disclosure. Method 100′ is described below in conjunction with FIGS. 13A-14, which are fragmentary cross-sectional views of an alternative structure 200′ fabricated according to embodiments of method 100′ in FIG. 12. FIGS. 15A-15C are fragmentary schematic cross-sectional views of alternative structures fabricated by the method of FIG. 1 or FIG. 12, according to one or more aspects of the present disclosure. FIG. 16 is a flowchart illustrating method 300 of forming a semiconductor structure according to embodiments of the present disclosure. Method 300 is described below in conjunction with FIGS. 17-31B. FIGS. 17-23B are fragmentary cross-sectional views of a structure 400 at different stages of fabrication according to embodiments of method 300 in FIG. 16. FIGS. 24-29B are fragmentary cross-sectional views of an alternative structure 400′ at different stages of fabrication according to embodiments of method 300 in FIG. 16. FIGS. 30-31B are fragmentary cross-sectional views of another alternative structure 400″ fabricated according to embodiments of method 300 in FIG. 16. In some embodiments, FIGS. 3, 5, 11, and 14 are fragmentary cross-sectional views taken along line A-A′ of FIG. 2, and FIGS. 4, 6-10B, 13A-13B, and 17-31B are fragmentary cross-sectional views taken along line B-B′ of FIG. 2. Method 100 (or 100′ or 300) is merely an example and is not intended to limit the present disclosure to what is explicitly illustrated in method 100 (or 100′ or 300). Additional steps can be provided before, during and after method 100 (or 100′ or 300), and some steps described can be replaced, eliminated, or moved around for additional embodiments of method 100 (or 100′ or 300). Not all steps are described herein in detail for reasons of simplicity. Because the structure 200 (or 200′, 400, 400′, 400″) will be fabricated into a semiconductor structure, the structure 200 (or 200′, 400, 400′, 400″) may be referred to herein as a semiconductor structure 200 (or 200′, 400, 400′, 400″) or a semiconductor device 200 (or 200′, 400, 400′, 400″) as the context requires. For avoidance of doubts, the X, Y and Z directions in FIGS. 2-11, 13A-15C, and 17-31B are perpendicular to one another and are used consistently throughout the present disclosure. Throughout the present disclosure, like reference numerals denote like features unless otherwise excepted. That is, material properties and comparisons thereof for various numbered elements described in association with a method or a figure should apply to the same numbered elements described in association with a different method or a different figure.

Referring to FIGS. 1-4, method 100 includes a block 102 where a structure 200 is formed or provided. FIGS. 3-4 illustrate fragmentary cross-sectional views of the structure 200 taken along line A-A′ and line B-B′ in FIG. 2, respectively. FIGS. 2-4 have been simplified for the sake of clarity to better understand the inventive concepts of the present disclosure. Additional features can be added in the structure 200, and some of the features described below can be replaced, modified, or eliminated in other embodiments of the structure 200.

Referring to FIG. 2, the structure 200 includes active regions 204 extending lengthwise along the X-direction and gate trenches 238 spanning lengthwise along the Y-direction. As will be described further below, the active region 204 includes a vertical stack of nanostructures (or channel members) stacked along the Z-direction.

Referring to FIGS. 3-4, the structure 200 includes a substrate 202 and various features that have been fabricated on the substrate 202. The structure 200 includes various features and/or components, such as top semiconductor layers 2080T, middle semiconductor layers 2080M, bottom semiconductor layers 2080B, gate spacers 222, inner spacers 228, top source/drain features 244, bottom source/drain features 230, a contact etch stop layer (CESL) 246, an interlayer dielectric (ILD) layer 248, a fin base structure 202B, isolation features 212, a CESL 232, and an ILD layer 234. In some embodiments, inner spacers 228 are optional.

In some embodiments, the fin base structure 202B protrudes from the substrate 202. The active region 204 includes a stack of bottom semiconductor layers (or bottom channel layers) 2080B disposed over the fin base structure 202B and a stack of top semiconductor layers (or top channel layers) 2080T disposed over the stack of bottom semiconductor layers 2080B. In some embodiments, the structure 200 includes more or less bottom semiconductor layers 2080B and/or top semiconductor layers 2080T. The middle semiconductor layers 2080M are disposed between the top semiconductor layers 2080T and the bottom semiconductor layers 2080B. The bottom semiconductor layers 2080B, the top semiconductor layers 2080T, and the middle semiconductor layers 2080M may be collectively or individually referred to as semiconductor layer(s) 2080 as the context requires. The insulation structure 216 is disposed between the two middle semiconductor layers 2080M. The insulation structure 216 may be a single layer/feature or a multilayer/feature structure, and in the depicted embodiment, includes an insulation structure 226M and an insulation structure 236. In some embodiments, the insulation structure 236 may be formed by a portion of the CESL 232 and the ILD layer 234. Along the X-direction, the active region 204 includes channel regions 204C interleaved by source/drain regions 204SD. In the source/drain regions 204SD, the active region 204 includes the bottom source/drain features 230 and the top source/drain features 244. The bottom semiconductor layers 2080B extend between the bottom source/drain features 230. The top semiconductor layers 2080T extend between the top source/drain features 244. Over the active region 204, a gate spacer layer 222 extends along sidewalls of the CESL 246 and the top source/drain feature 244. The inner spacers 228 are disposed under the gate spacers 222 and adjacent to the bottom source/drain features 230 and the top source/drain features 244. The gate trench 238 includes openings 240 between the neighboring semiconductor layers 2080 and between the bottommost semiconductor layer 2080 and the fin base structure 202B.

The substrate 202, the fin base structure 202B, and the semiconductor layers 2080 include an elementary semiconductor, such as silicon and/or germanium; a compound semiconductor, such as silicon carbide, gallium arsenide, gallium phosphide, indium phosphide, indium arsenide, indium antimonide, or a combination thereof; an alloy semiconductor, such as SiGe, GaAsP, AlInAs, AlGaAs, GalnAs, GalnP, GalnAsP, or a combination thereof; or a combination thereof. The substrate 202, the fin base structure 202B, and the semiconductor layers 2080 may include IV and III—V group materials. In the depicted embodiment, the substrate 202, the fin base structure 202B, and the semiconductor layers 2080 include silicon. In some embodiments, the top semiconductor layers 2080T and the bottom semiconductor layers 2080B include different semiconductor materials, such as silicon and silicon germanium, respectively, or vice versa. In some embodiments, the substrate 202 is a semiconductor-on-insulator substrate, such as a silicon-on-insulator substrate, a silicon germanium-on-insulator substrate, or a germanium-on-insulator substrate. The substrate 202 and the fin base structure 202B may include various doped regions, such as p-wells and n-wells. The n-wells are doped with n-type dopants, such as phosphorus, arsenic, other n-type dopant, or a combination thereof. The p-wells are doped with p-type dopants, such as boron, indium, other p-type dopant, or a combination thereof.

The isolation features 212 electrically isolate active device regions and/or passive device regions. For example, the isolation features 212 separate and electrically isolate the fin base structure 202B from each other and/or other device regions/features. The isolation features 212 include silicon oxide, silicon nitride, silicon oxynitride, other suitable isolation material (for example, including silicon, oxygen, nitrogen, carbon, etc.), or a combination thereof. The isolation features 212 may have a multilayer structure. For example, the isolation features 212 include a bulk dielectric (e.g., an oxide layer) over a dielectric liner (for example, silicon nitride, silicon oxide, silicon oxynitride, silicon oxycarbonitride, or a combination thereof). In another example, the isolation features 212 include a bulk dielectric over a doped liner, such as a boron silicate glass (BSG) liner and/or a phosphosilicate glass (PSG) liner. Dimensions and/or characteristics of the isolation features 212 are configured to provide shallow trench isolation (STI) structures, deep trench isolation (DTI) structures, local oxidation of silicon (LOCOS) structures, other suitable isolation structures, or a combination thereof. In the depicted embodiment, the isolation features 212 may be STIs.

The gate spacers 222 and the inner spacers 228 include a dielectric material, which may include silicon, oxygen, carbon, nitrogen, other suitable dielectric constituent, or a combination thereof (e.g., silicon oxide, silicon nitride, silicon oxynitride, silicon carbide, silicon carbonitride, silicon oxycarbide, silicon oxycarbonitride, or a combination thereof). The gate spacers 222 and the inner spacers 228 may include different materials and/or different configurations (e.g., different numbers of layers). In some embodiments, the gate spacers 222, the inner spacers 228, or a combination thereof have a multilayer structure. In some embodiments, the gate spacers 222 include more than one set of spacers, such as seal spacers, offset spacers, sacrificial spacers, dummy spacers, main spacers, or a combination thereof. The various sets of spacers may have different compositions.

The bottom source/drain features 230 and the top source/drain features 244 have the same or different compositions and/or materials depending on configurations of their respective transistors. The bottom source/drain features 230 and the top source/drain features 244 may be doped with n-type dopants and/or p-type dopants. In some embodiments, the bottom source/drain features 230 and/or the top source/drain features 244 include silicon that may be doped with carbon, phosphorous, arsenic, other n-type dopant, or a combination thereof (e.g., Si:C epitaxial source/drains, Si:P epitaxial source/drains, or Si:C:P epitaxial source/drains). In some embodiments, the bottom source/drain features 230 and/or the top source/drain features 244 include silicon germanium or germanium, which may be doped with boron, other p-type dopant, or a combination thereof (e.g., Si:Ge:B epitaxial source/drains). In the depicted embodiment, the bottom source/drain features 230 include silicon germanium doped with boron, and the top source/drain features 244 include silicon doped with phosphorous. In some embodiments, the bottom source/drain features 230 and/or the top source/drain features 244 include more than one epitaxial semiconductor layer, where the epitaxial semiconductor layers may include the same or different materials and/or the same or different dopant concentrations. In some embodiments, the bottom source/drain features 230 and/or the top source/drain features 244 include materials and/or dopants that achieve desired tensile stress and/or compressive stress in adjacent channel regions (e.g., formed by the semiconductor layers 2080T and the semiconductor layers 2080B). As used herein, source/drain region, source/drain feature, epitaxial source/drain, epitaxial source/drain feature, etc. may refer to a source of a device, a drain of a device, or a source and/or a drain of multiple devices.

The ILD layer 248 and the ILD layer 234 include a dielectric material including, for example, silicon oxide, carbon doped silicon oxide, silicon nitride, silicon oxynitride, tetraethyl orthosilicate (TEOS)-formed oxide, BSG, PSG, borophosphosilicate glass (BPSG), fluorosilicate glass (FSG), xerogel, aerogel, amorphous fluorinated carbon, parylene, benzocyclobutene-based (BCB) dielectric material, polyimide, other suitable dielectric material, or a combination thereof. In some embodiments, the ILD layer 248 and/or the ILD layer 234 include a dielectric material having a dielectric constant that is less than a dielectric constant of silicon dioxide. The CESL 232 and the CESL 246 include a material different than a material of the ILD layer 234 and the ILD layer 248, respectively. In some embodiments, CESL 232 and the CESL 246 include silicon nitride and the ILD layer 234 and the ILD layer 248 include silicon oxide. In some embodiments, CESL 232 and the CESL 246 include Si₃N₄. The ILD layer 234, the ILD layer 248, the CESL 232, the CESL 246, or a combination thereof may include a multilayer structure. The ILD layer 234, the ILD layer 248, the CESL 232, and the CESL 246 may be collectively referred to as a dielectric structure.

In some embodiments, the insulation structure 226M includes a dielectric material, which may include silicon, oxygen, carbon, nitrogen, other suitable dielectric constituent, or a combination thereof (e.g., silicon oxide, silicon nitride, silicon oxynitride, silicon carbide, silicon carbonitride, silicon oxycarbide, silicon oxycarbonitride, or a combination thereof). In furtherance of the depicted embodiment, the source/drain features 244 are separated and/or electrically isolated from the source/drain features 230 by the insulation structure 236.

Referring to FIGS. 1 and 5-6, method 100 includes a block 104 where a bottom gate electrode including a first type work function metal (WFM) layer is formed to wrap around the stack of bottom semiconductor layers 2080B.

Before forming the bottom gate electrode, an interfacial layer 252 and a gate dielectric layer 254 are formed. The interfacial layer 252 interfaces the semiconductor layers 2080 and the fin base structure 202B in the channel region 204C. The interfacial layer 252 may include a dielectric material, such as SiO₂, SiGeOx, HfSiO, SiON, other dielectric material, or a combination thereof. The interfacial layer 252 may be formed by chemical oxidation, thermal oxidation, atomic layer deposition (ALD), chemical vapor deposition (CVD), and/or other suitable method. The gate dielectric layer 254 is disposed over the interfacial layer 252 and wraps around the semiconductor layers 2080 and the insulation structure 226M. In some embodiments, the gate dielectric layer 254 includes a high-k dielectric layer. The high-k dielectric layer includes a high-k dielectric material, which generally refers to dielectric materials having a dielectric constant that is greater than a dielectric constant of silicon dioxide (k≈3.9), such as HfO₂, HfSIO, HfSiO₄, HfSION, HfLaO, HfTaO, HfTIO, HfZrO, HfAlOx, ZrO, ZrO₂, ZrSiO₂, AlO, AlSiO, Al₂O₃, TIO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr) TiO₃ (BST), Si₃N₄, HfO₂—Al₂O₃, other high-k dielectric material, or a combination thereof. For example, the gate dielectric layer 254 includes a hafnium-based oxide (e.g., HfO₂) layer and/or a zirconium-based oxide (e.g., ZrO₂) layer. The gate dielectric layer 254 may be formed by ALD, physical vapor deposition (PVD), CVD, oxidation, and/or other suitable methods. In some embodiments, the interfacial layer 252 and/or the gate dielectric layer 254 have a multilayer structure. In some embodiments, the interfacial layer 252 and the gate dielectric layer 254 have thicknesses in a range of about 0.5 nm to about 2 nm and in a range of about 1 nm to about 5 nm, respectively.

The bottom gate electrode may be disposed over a bottom portion of the gate dielectric layer 254. The bottom portion of the gate dielectric layer 254 may be around the fin base structure 202B and the bottom semiconductor layers 2080B. In the depicted embodiment, the bottom portion of the gate dielectric layer 254 is also around a bottom portion of the bottom one of the middle semiconductor layers 2080M. The bottom gate electrode includes at least one electrically conductive gate layer. The electrically conductive gate layer includes an electrically conductive material, such as Al, Cu, Ti, Ta, W, Mo, Co, TaN, NiSi, CoSi, TiN, WN, TiAl, TiAlN, TaCN, TaC, TaSiN, other electrically conductive material, or a combination thereof. In various embodiments, the bottom gate electrode may be formed by ALD, PVD, CVD, e-beam evaporation, or other suitable process.

In the depicted embodiment, the bottom gate electrode includes a first type WFM layer 258. The first type WFM layer 258 is a conductive layer tuned to have a desired work function, such as an n-type work function or a p-type work function, for an n-type transistor or a p-type transistor, respectively. The first type WFM layer 258 includes work function metal(s) and/or alloys thereof, such as Ti, Ta, Al, Ag, Mn, Zr, W, Ru, Mo, TiC, TiAl, TIAIC, TIAISIC, TaC, TaCN, TaSiN, TiSiN, TiN, TaN, TaSN, WN, WCN, ZrSi₂, MoSi₂, TaSi₂, NiSi₂, TaAl, TaAIC, TaSiAIC, TiAlN, or a combination thereof. In some embodiments, the first type WFM layer 258 is used for forming a PMOS device. In such embodiments, the first type WFM layer 258 is a p-type work function layer. The p-type work function layer is capable of providing a work function value suitable for the device, such as equal to or greater than about 4.8 eV. The p-type work function layer may include metal, metal carbide, metal nitride, other suitable materials, or a combination thereof. Example p-type work function materials include Ti, TiN, TaN, Ru, Mo, Al, WN, ZrSi₂, MoSi₂, TaSiz, NiSi₂, or WN. In some other embodiments, the first type WFM layer 258 is used for forming an NMOS device. In such embodiments, the first type WFM layer 258 is an n-type work function layer. The n-type work function layer is capable of providing a work function value suitable for the device, such as equal to or less than about 4.5 eV. The n-type work function layer may include metal, metal carbide, metal nitride, or a combination thereof. Example n-type work function materials include Ti, Al, Ag, Mn, Zr, TiAl, TiAlC, TaC, TaCN, TaSIN, TaAl, TaAIC, or TiAlN.

The first type WFM layer 258 may be deposited over the gate dielectric layer 254 using an ALD process, a CVD process, a PVD process, an electroplating process, an electroless plating process, one or more other applicable processes, or a combination thereof. In some embodiments, the first type WFM layer 258 is deposited in the gate trench 238 to wrap around the top semiconductor layers 2080T and the bottom semiconductor layers 2080B, and then etched back from the top semiconductor layers 2080T. After etching back, a portion of the first type WFM layer 258 remains in a bottom gate region 210B, and a top portion of the gate dielectric layer 254 in a top gate region 210T is exposed as depicted. The bottom gate region 210B refers to a region of the trench 238 below the top surface of the remaining first type WFM layer 258, and the top gate region 210T refers to a region of the trench 238 above the top surface of the remaining first type WFM layer 258. A top surface of the first type WFM layer 258 may be above a bottom surface of the bottom one of the middle semiconductor layers 2080M and below a top surface of the top one of the middle semiconductor layers 2080M.

In the depicted embodiment, it may allow only work function metal (e.g., the first type WFM layer 258) deposited inside the gate trench 238 due to gate pitch limit. In some other embodiments not depicted, the bottom gate electrode further includes a bulk layer over the first type WFM layer 258 and in the bottom gate region 210B. The bulk layer includes a suitable conductive material, such as Al, W, Cu, Ti, Ta, TiN, TaN, polysilicon, other suitable metal(s) and/or alloys thereof, or a combination thereof. The bottom gate electrode and portions of the interfacial layer 252 and the gate dielectric layer 254 thereunder may be collectively referred to as a bottom gate segment 250B.

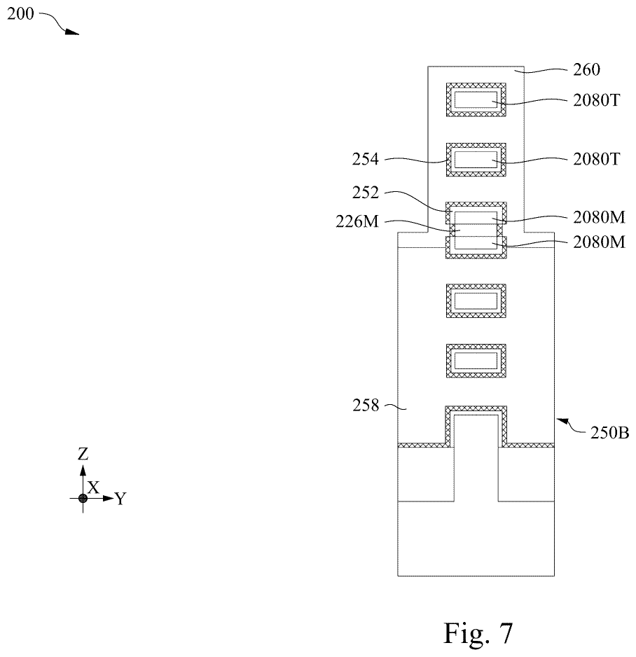

Referring to FIGS. 1 and 7, method 100 includes a block 106 where a second type WFM layer 260 is formed over the top portion of the gate dielectric layer 254. The second type WFM layer 260 may be around the top semiconductor layers 2080T, a top portion of the bottom one of the middle semiconductor layers 2080M, and the insulation structure 226M. The second type WFM layer 260 may be on top surfaces of the first type WFM layer 258. The first type and the second type may be the same or different. In some embodiments, the first type WFM layer 258 is a p-type work function layer and the second type WFM layer 260 is an n-type work function layer. In some embodiments, both the first type WFM layer 258 and the second type WFM layer 260 are n-type work function layers. The second type WFM layer 260 may be deposited using an ALD process, a CVD process, a PVD process, an electroplating process, an electroless plating process, one or more other applicable processes, or a combination thereof.

Referring to FIGS. 1 and 8-9, method 100 includes a block 108 where a gas treatment 262 is performed to the structure 200, thereby forming a passivation layer 264 over the second type WFM layer 260. The gas treatment 262 may be performed in-situ with the forming of the second type WFM layer 260 at block 106. In some embodiments, forming of the second type WFM layer 260 and performing the gas treatment 262 are in a same chamber.

In some embodiments, the gas treatment 262 includes applying a gas to the structure 200 including the second type WFM layer 260. The gas may include a silicon-containing gas, a carbon-containing gas, or a combination thereof. The silicon-containing gas may include silane (SiH₄), disilane (Si₂H₆), other suitable gases, or a combination thereof. The carbon-containing gas may include methane (CH₄), ethane (C₂H₆), other suitable gases, or a combination thereof. In some embodiments, the gas includes the silicon-containing gas.

Applying the gas to the structure 200 may include performing a thermal soak process at a temperature lower than about 500 degree C. The temperature range is not randomly chosen but rather specifically configured to facilitate the forming of the passivation layer 264, while avoiding damaging existing features of the structure 200. In some embodiments, the thermal soak process heats the structure 200 in an atmosphere of the gas at the temperature for a time duration. In some embodiments, the gas is adsorbed onto exposed surfaces (e.g., top surfaces and sidewalls) of the second type WFM layer 260. The gas may react with materials at the exposed surfaces of the second type WFM layer 260 to form a silicon-metal bond, a silicon-nitrogen bond, a carbon-metal bond, a carbon-nitrogen bond, or a combination thereof. In other words, silicon and/or carbon atoms in the gas may be attached to the surfaces of the second type WFM layer 260. In the embodiments where the gas includes a silicon-containing gas, the gas reacts with the materials at the exposed surfaces of the second type WFM layer 260, thereby forming a silicon-metal bond, a silicon-nitrogen bond, or both. In the embodiments where the gas includes a carbon-containing gas, the gas reacts with the materials at the exposed surfaces of the second type WFM layer 260, thereby forming a carbon-metal bond, a carbon-nitrogen bond, or both. Various parameters can be tuned to form the bonds, such as composition of the gas, the temperature, the time duration, pressure, gas flow rate, other suitable parameters, or combinations thereof.

In some embodiments, applying the gas to the structure 200 includes a plasma process. Plasma (e.g., Si radicals, C radicals) may be generated from the gas. The plasma may be bombarded toward the exposed surfaces of the second type WFM layer 260 and react with the materials at the exposed surfaces of the second type WFM layer 260. Similar bonds as described above in the thermal soak process may be formed. Various parameters can be tuned to form the bonds, such as composition of the gas, the temperature, time duration, pressure, source power, RF bias voltage, RF bias power, gas flow rate, other suitable parameters, or combinations thereof.

In some embodiments, after applying the gas to the structure 200, the gas treatment 262 includes exposing the structure 200 in an atmosphere (e.g., air) including oxygen. Silicon atoms bonded to the surfaces of the second type WFM layer 260 may be oxidized to form the passivation layer 264. In such embodiments, the passivation layer 264 includes silicon oxide (e.g., SiO₂, SiO). In some embodiments, a concentration of silicon oxide in the passivation layer 264 is greater than about 95% and a total concentration of metals in the passivation layer 264 is less than about 5%. In some embodiments, the passivation layer 264 excludes metal(s). In some embodiments, the passivation layer 264 excludes a metal nitride. In the embodiments where the gas includes carbon-containing gas, the passivation layer 264 includes metal carbide, such as a metal carbide including an n-type work function material as described above. In embodiments where the gas includes both the carbon-containing gas and the silicon-containing gas, the passivation layer 264 includes silicon oxide and a metal carbide. In embodiments where the gas includes the carbon-containing gas but not the silicon-containing gas, exposing the structure 200 in the atmosphere including oxygen may be omitted. In some embodiments, between applying the gas to the structure 200 and exposing the structure 200 in the atmosphere including oxygen, the gas treatment 262 includes purging the chamber with the structure 200 using an inert gas, such as nitrogen.

The passivation layer 264 may have a thickness of about 0.5 nm to about 1 nm. The passivation layer 264 may bedetected by an appropriate metrology technique such as using energy-dispersive X-ray spectroscopy (EDS), electron energy loss spectroscopy (EELS), secondary ion mass spectrometry (SIMS), or other appropriate metrology technique.

The passivation layer 264 may prevent oxygen diffusion from environment to the second type WFM layer 260, thus mitigating native oxidation of metal(s) in the second type WFM layer 260. This may provide additional Vt tuning method, improve control of the Vt of the second type WFM layer 260, and/or prevent Vt shift, such as Vt shift during a patterning process to the gate structure 250.

Referring to FIGS. 1 and 10A-11, method 100 includes a block 110 where an adhesion layer 266 and a metal fill layer 268 are formed over the passivation layer 264. The adhesion layer 266, the metal fill layer 268, the passivation layer 264, and the second type WFM layer 260 collectively form a top gate electrode. The top gate electrode and portions of the interfacial layer 252 and the gate dielectric layer 254 thereunder may be collectively referred to as a top gate segment 250T. The top gate segment 250T and the bottom gate segment 250B are collectively referred to as a gate structure 250.

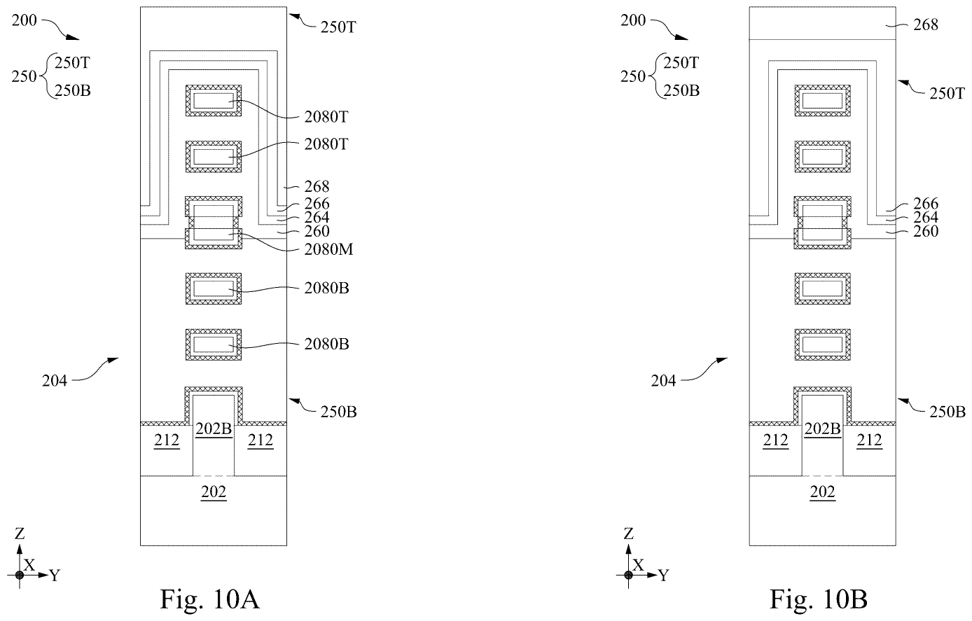

Referring to FIG. 10A, in some embodiments, the metal fill layer 268 is disposed on both top surfaces and sidewalls of the adhesion layer 266. In such embodiments, the metal fill layer 268 extends to below a topmost surface of the adhesion layer 266. The metal fill layer 268 may extend to below a topmost surface of the top semiconductor layers 2080T, and laterally extend between the top semiconductor layers 2080T of the neighboring active regions 204 along the Y-direction. In such embodiments, the adhesion layer 266 has a thickness in a range between about 10 angstroms and about 25 angstroms.

Referring to FIG. 10B, in some alternative embodiments, the metal fill layer 268 is disposed on the top surface but not the sidewalls of the adhesion layer 266. This may be because of limited distance between the neighboring active regions 204. In such embodiments, the adhesion layer 266 may have a thickness greater than about 25 angstroms. In such embodiments, the metal fill layer 268 is above and not laterally disposed between the top semiconductor layers 2080T of the neighboring active regions 204 along the Y-direction.

In some embodiments, the adhesion layer 266 includes TIN, TaN, or a combination thereof. In some embodiments, the metal fill layer 268 includes a suitable conductive material, such as tungsten (W), cobalt (Co), ruthenium (Ru), iridium (Ir), Al, W, Cu, Ti, Ta, other suitable metal(s) and/or alloys thereof, or a combination thereof. In some embodiments, the metal fill layer 268 includes a low resistance metal, such as W, Co, Ru, Ir, or a combination thereof. A plurality of deposition processes may be performed to form the adhesion layer 266 over the passivation layer 264, and to form the metal fill layer 268 over the adhesion layer 266. In some embodiments, the deposition processes may include ALD, CVD, PVD, or combinations thereof.

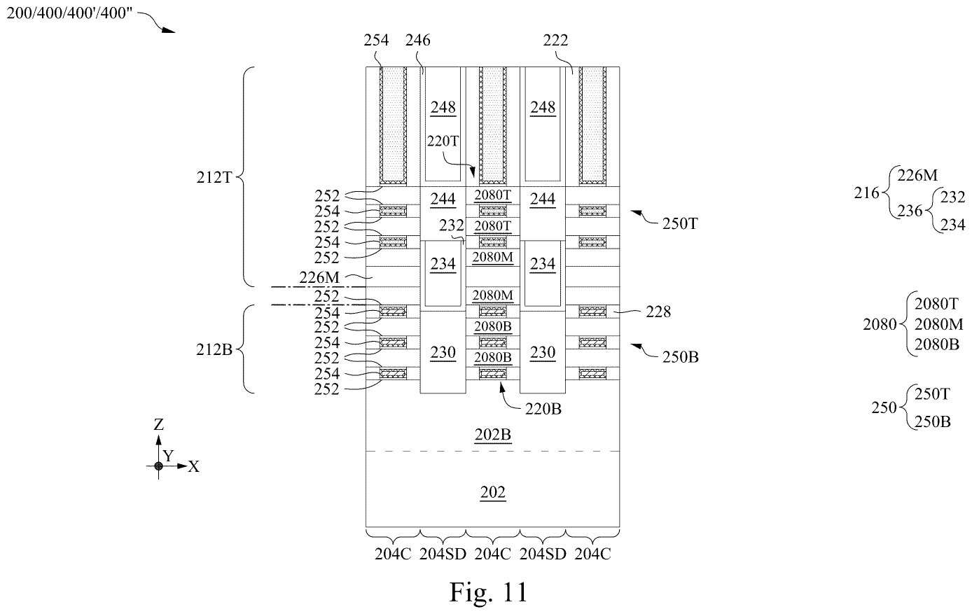

Referring to FIG. 11, the structure 200 includes a device stack, such as a bottom device 212B disposed over the substrate 202 and a top device 212T vertically stacked over the bottom device 212B. The gate structure 250 is insulated from the top source/drain features 244 and the bottom source/drain features 230 by the inner spacer features 228. In some embodiments, the inner spacer features 228 are optional.

The top device 212T and the bottom device 212B each include at least one electrically functional device, such as a top transistor 220T and a bottom transistor 220B, respectively. The top transistor 220T includes elements such as the top semiconductor layers 2080T, the top source/drain features 244 connected by the top semiconductor layers 2080T, and the top segment 250T of the gate structure 250. The bottom transistor 220B includes elements such as the fin base structure 202B, the bottom semiconductor layers 2080B, the bottom source/drain features 230 connected by the bottom semiconductor layers 2080B, and the bottom segment 250B of the gate structure 250. The structure 200 thus includes a transistor stack having a top transistor (e.g., the transistor 220T) and a bottom transistor (e.g., the transistor 220B). In some embodiments, the transistor 220B and the transistor 220T are transistors of an opposite conductivity type. For example, the transistor 220B is a p-type transistor, and the transistor 220T is an n-type transistor. In such embodiments, the transistor 220B and the transistor 220T form a CFET. In some embodiments, the transistor 220B and the transistor 220T are transistors of a same conductivity type. For example, the transistor 220B and the transistor 220T are both n-type transistors.

The structure 200 may undergoes further processes to form various features and regions known in the art. For example, subsequent processing may form additional interlayer dielectric (ILD) layer(s), contacts/vias/lines and multilayers interconnect features (e.g., metal layers and interlayer dielectrics) over the substrate 202, configured to connect the various features to form a functional circuit that may include one or more devices including the semiconductor device 200. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure.

In the embodiments represented by FIGS. 3-11, the structure 200 is fabricated monolithically, and thus can be referred to as a monolithic stacked device structure 200. Referring to FIGS. 12-14, an alternative structure 200′ may be fabricated according to method 100′ of FIG. 12. The alternative structure 200′ is fabricated sequentially, and thus can be referred to as a sequential stacked device structure 200′. A top view of the alternative structure 200′ is the same as in FIG. 2.

Referring to FIGS. 12-14, method 100′ includes a block 112 where a bottom device 212B′ similar as described above is formed. The bottom device 212B′ may include a transistor 220B′. The transistor 220B′ may include similar elements as the transistor 220B described above, such as the fin base structure 202B, the bottom semiconductor layers 2080B disposed over the fin base structure 202B, the bottom segment 250B of gate structure 250 wrapping around the bottom semiconductor layers 2080B, the bottom source/drain features 230 connected to the bottom semiconductor layers 2080B, and the ILD layer 234 and the CESL over the bottom source/drain features 230.

Referring to FIGS. 12-14, method 100′ includes a block 114 where the bottom device 212B′ is bonded or attached to a device precursor for fabricating the top device 212T′.

In some embodiments, the device precursor includes a semiconductor layer stack disposed over a respective substrate. The semiconductor layer stack includes semiconductor layers (to form the top semiconductor layers 2080T) and sacrificial semiconductor layers (not depicted) stacked vertically (e.g., along the Z-direction) in an interleaving and/or alternating configuration from a top surface of the respective substrate. The sacrificial semiconductor layers may include different compositions than the top semiconductor layers 2080T. In some embodiments, the sacrificial layers include semiconductor materials such as silicon germanium.

In some embodiments, bonding or attaching the device precursor to the bottom device 212B′ includes flipping over the device precursor of the top device 212T′, contacting the device precursor of the top device 212T′ to the bottom device 212B′ and performing an annealing process. For example, a bonding dielectric layer 270T of the device precursor is brought into contact with a bonding dielectric layer 270B of the bottom device 212B′ (or vice versa) under a temperature, a pressure, an atmosphere, or a combination thereof for a time that effectuates bonding of the bonding dielectric layer 270T and the bonding dielectric layer 270B. In some embodiments, one or both of the bonding dielectric layer 270T and the bonding dielectric layer 270B may include a plasma activated bonding dielectric layer. In some embodiments, one or both of the bonding dielectric layer 270T and the bonding dielectric layer 270B may include silicon oxide, such as SiO₂. After bonding, the bottom device 212B′ is attached to and electrically isolated from the device precursor of the top device 212T′ by an isolation structure 270, which includes the bonding dielectric layer 270T and the bonding dielectric layer 270B. In some embodiments, a thickness of isolation structure 270 is about 10 nm to about 100 microns.

Referring to FIGS. 12-14, method 100′ includes a block 116 where the device precursor of the top device 212T′ is fabricated. In some embodiments, a thinning process is performed to remove the respective substrate and the top sacrificial semiconductor layer from the device precursor. The semiconductor layer stack is patterned to form fin-shaped structures extending from the isolation structure 270, the fin-shaped structures include the top semiconductor layers 2080T. Dummy gate stacks are formed over channel regions 204C of the fin-shaped structures, the gate spacers 222 are formed along sidewalls of dummy gate stacks, and source/drain recesses are formed in the source/drain regions 204SD of the fin-shaped structures, thereby exposing the isolation structure 270. In some embodiments, the dummy gate stacks extend lengthwise along the Y-direction. For example, the dummy gate stacks may include a dummy gate dielectric, a dummy gate electrode, a hard mask, other suitable layers, or a combination thereof. The inner spacers 228 under the gate spacers 222 are formed, the top source/drain features 244 are formed in the source/drain recesses, and the CESL 246 and the ILD layer 248 are formed over the top source/drain features 244. The top semiconductor layers 2080T extend between the top source/drain features 244.

The dummy gate stacks are then removed to form gate trenches, after which a channel release process is performed to selectively remove the sacrificial semiconductor layers to form gaps/openings between the top semiconductor layers 2080T and between the semiconductor layers 2080T and the isolation structure 270 (e.g., by a selective etching process). As a result of forming the gate trenches and the gaps/openings, the semiconductor layers 2080T of the top device 212T′ are exposed and ready for subsequent formation of the top segment 250T of the gate structure 250 thereupon. The interfacial layer 252 is formed over the semiconductor layers 2080T, and the gate dielectric layer 254 is formed over the interfacial layer 252, the gate spacers 222, the inner spacers 228, and the isolation structure 270.

Referring to FIGS. 12-14, method 100′ includes blocks 106 to 110 as described above in method 100 of FIG. 1. Compared to the structure 200 in FIGS. 10A-11, differences include that, in the alternative structure 200′, the top segment 250T and the bottom segment 250B of the gate structure 250 are isolated by the isolation structure 270. The top source/drain features 244 and the bottom source/drain features 230 are isolated by the isolation structure 270. The alternative structure 200′ may undergo further processes similar as described above to the structure 200.

Although FIGS. 2-11 and 13A-14 illustrate stacked transistor structures having GAA transistors, other examples of semiconductor devices (e.g., multigate devices, stacked transistor structures having any combination of transistors, such as planar, FinFET, nanosheet, and nanowire transistors) may benefit from aspects of the present disclosure. For example, the top device 212T/212T′ may include a GAA transistor and the bottom device 212B/212B′ may include one or more FinFET transistors (shown in FIG. 15A). In some embodiments, the top device 212T/212T′ and the bottom device 212B/212B′ each include one or more FinFET transistors (shown in FIG. 15B). In some embodiments, the top device 212T/212T′ includes one or more FinFET transistors and the bottom device 212B/212B′ includes a GAA transistor (shown in FIG. 15C). In FIGS. 15A-15C, the isolation structure 270 is optional. The isolation structure 270 may be included in a sequentially formed stacked transistor structure. The isolation structure 270 may be omitted in a monolithically formed stacked transistor structure.

Referring to FIGS. 16 and 2-4, method 300 includes a block 302 where a structure 400 is provided or formed. A fragmentary top view of the structure 400 is as in FIG. 2. FIGS. 3-4 illustrate fragmentary cross-sectional views of the structure 400 taken along line A-A′ and line B-B′ in FIG. 2, respectively. Operations at block 302 are similar to the operations at block 102 of method 100 as described above. At this stage, the structure 400 is similar to the structure 200 at the stage of block 102.

Referring to FIGS. 16-17, method 300 includes a block 304 where a first type WFM layer 258 is formed to wrap around the stack of top semiconductor layers 2080T and the stack of bottom semiconductor layers 2080B.

Before forming the first type WFM layer 258, an interfacial layer 252 and a gate dielectric layer 254 are formed similarly as described above at block 104. The first type WFM layer 258 may be formed over the gate dielectric layer 254 using an ALD process, a CVD process, a PVD process, an electroplating process, an electroless plating process, one or more other applicable processes, or a combination thereof. The first type WFM layer 258 may wrap around the top semiconductor layers 2080T, the bottom semiconductor layers 2080B, the middle semiconductor layers 2080B, and the insulation structure 226M. Composition of the first type WFM layer 258 is similar as described above. In the depicted embodiment, a portion of the trench 238 adjacent to a sidewall of the first type WFM layer 258 remains unfilled.

Referring to FIGS. 16 and 18-19, method 300 includes a block 306 where a gas treatment 402 is performed to the structure 400, thereby forming a barrier layer 404 over the first type WFM layer 258. The gas treatment 402 may be performed in-situ with the forming of the first type WFM layer 258 at block 304. In some embodiments, forming the first type WFM layer 258 and performing the gas treatment 402 are in a same chamber. The gas treatment 402 is similar to the gas treatment 262 described above, and composition and a thickness of the barrier layer 404 are similar to those of the passivation layer 264. The barrier layer 404 is disposed over top surfaces and sidewalls of the first type WFM layer 258. The barrier layer 404 may be detected by an appropriate metrology technique such as using energy-dispersive X-ray spectroscopy (EDS), electron energy loss spectroscopy (EELS), secondary ion mass spectrometry (SIMS), or other appropriate metrology technique.

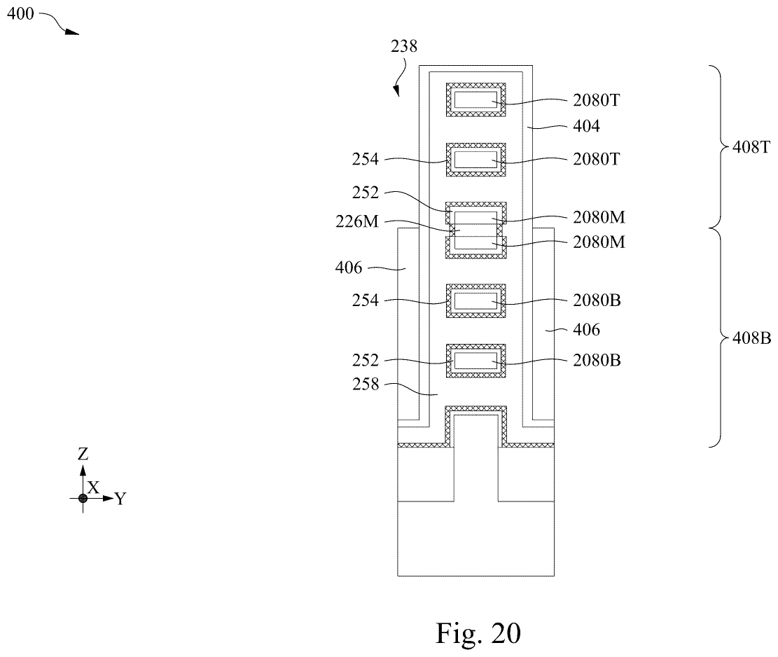

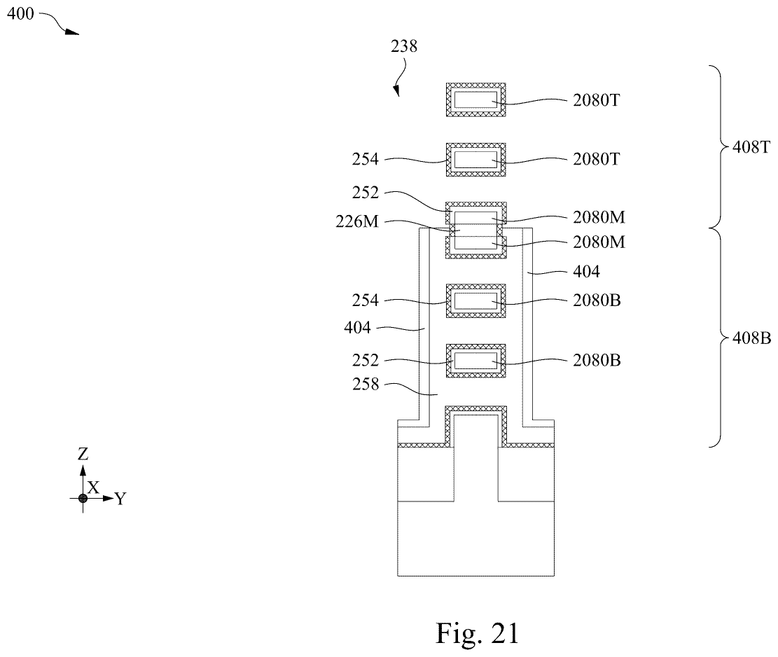

Referring to FIGS. 16 and 20-21, method 300 includes a block 308 where top portions of the first type WFM layer 258 and the barrier layer 404 are removed. Operations at block 308 may include depositing a bottom anti-reflective coating (BARC) layer 406 over the barrier layer 404, etching back the BARC layer 406 to expose the top portion of the barrier layer 404 (as in FIG. 20), etching back the top portions of the first type WFM layer 258 and the barrier layer 404 above the remaining BARC layer 406, and removing the remaining BARC layer 406 (as in FIG. 21).

The BARC layer 406 may be deposited over the barrier layer 404 using CVD, spin-on processes, or other suitable processes. In some implementations, the BARC layer 406 may include silicon oxynitride (SiON), silicon oxycarbide, a polymer, or other suitable materials. The BARC layer 406 and the barrier layer 404 may include different compositions. After the deposition of the BARC layer 406, it is selectively etched back to expose a portion of the barrier layer 404 as depicted in FIG. 20. The etching back may include use of a dry etch process. The dry etch process may include use of plasma of argon (Ar), oxygen (O₂), nitrogen (N₂), hydrogen (H₂), or a combination thereof. A top surface of a remaining BARC layer 406 may be above a bottom surface of the bottom one of the middle semiconductor layers 2080M, and below a top surface of the top one of the middle semiconductor layers 2080M. In some embodiments, the top surface of a remaining BARC layer 406 is between a top surface and a bottom surface of the insulation structure 226M. A region of the trench 238 below the top surface of the remaining BARC layer 406 may be referred to as a bottom gate region 408B, and a region of the trench 238 above the top surface of the remaining BARC layer 406 may be referred to as a top gate region 408T.

Then, the barrier layer 404 and the first type WFM layer 258 not covered by the remaining BARC layer 406 is etched back. After etching back, topmost surfaces of the barrier layer 404 and the first type WFM layer 258 may at the same level as the top surfaces of the remaining BARC layer 406. The etching back may include a controlled selective etching of the barrier layer 404 and the first type WFM layer 258 without substantially etching the semiconductor layers 2080T and 2080M, the interfacial layer 252, the gate dielectric layer 254, the insulation structure 226M, and the BARC layer 406. For example, as part of the etch-back process, an etchant selectivity may be selected such that metal is etched at a higher rate than dielectric. As shown in FIG. 21, the etching back removes the top portions of the barrier layer 404 and the first type WFM layer 258 in the top gate region 408T while the bottom portions of the barrier layer 404 and the first type WFM layer 258 remain in the bottom gate region 408B. In the depicted embodiment, the etching back partially or fully exposes side surfaces of the gate dielectric layer 254 on the insulation structure 226M. The remaining BARC layer 406 is then removed using processes such as an ashing process or a dry etch process.

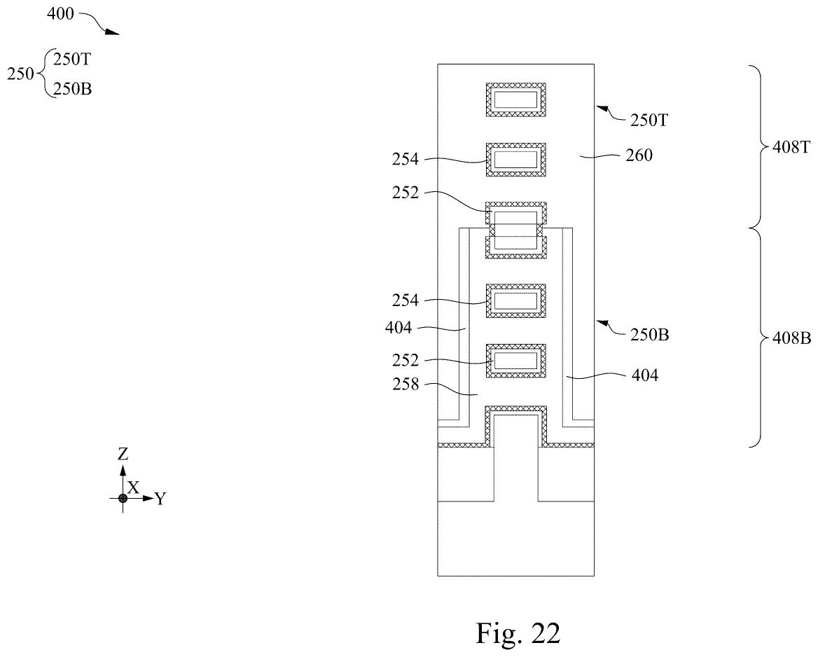

Referring to FIGS. 16 and 22, method 300 includes a block 310 where a second type WFM layer 260 is formed to wrap around the top semiconductor layers 2080T. Operations at block 310 may be similar to the operations at block 106. Differences from the operations at block 106 include the follows. In the structure 400, the first type WFM layer 258 and the second type WFM 260 are of different types. In some embodiments, the first type WFM layer 258 is p-type and the second type WFM 260 is n-type. In the depicted embodiment, the second type WFM layer 260 completely fills the remaining trench 238 (as shown in FIG. 21), and that a planarization process (e.g., a CMP process) may be performed to remove excess materials. The interfacial layer 252, the gate dielectric layer 254, the first type WFM layer 258, the barrier layer 404, and the second type WFM layer 260 in the bottom gate region 408B collectively form the bottom segment 250B of the gate structure 250. The interfacial layer 252, the gate dielectric layer 254, and the second type WFM layer 260 in the top gate region 408T collectively form the top segment 250T of the gate structure 250.

The barrier layer 404 is disposed between the first type WFM layer 258 and the second type WFM layer 260. The barrier layer 404 may avoid or reduce diffusion of metals from the second type WFM layer 260 to the first type WFM layer 258, for example, during a middle-end-of-line (MEOL) process, thus mitigate Vt shift of the first type WFM layer 258.

In some other embodiments, at block 310, the second type WFM layer 260 partially fills the remaining trench 238. In following procedures, more layers (e.g., the adhesion layer 266 and the metal fill layer 268 as described above) may be deposited over the second type WFM layer 260 and in the remaining trench 238.

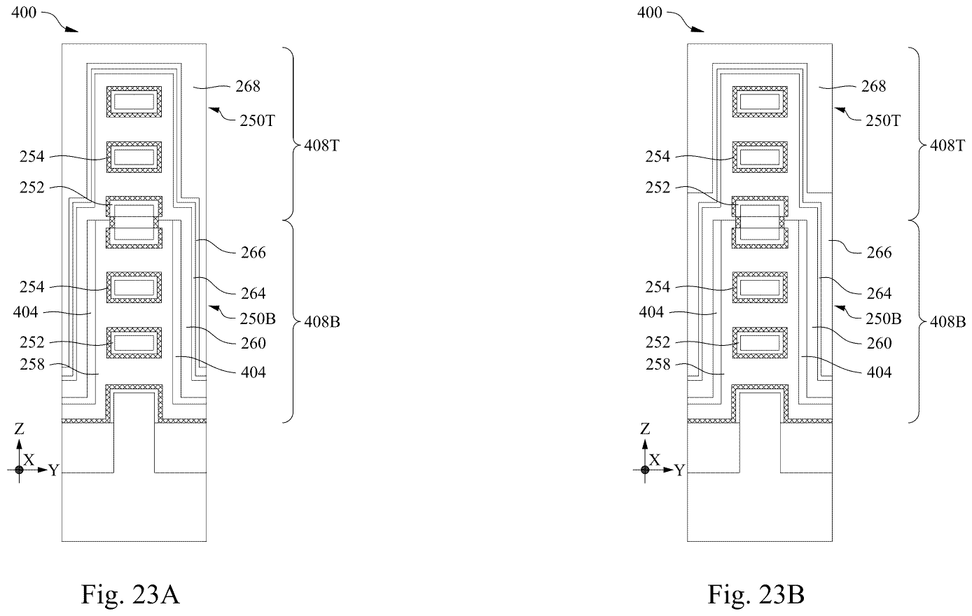

Referring to FIGS. 16 and 23A-23B, in some embodiments, method 300 includes block 312 similar to block 108. In some embodiments, method 300 includes block 314 similar to block 110. In such embodiments, the passivation layer 264 may be formed as described above and between the second type WFM layer 260 and the adhesion layer 266. In other words, the barrier layer 404 and the passivation layer 264 in the present disclosure may be formed in a same structure (e.g., structure 400 in FIGS. 23A-23B). Blocks 312 and/or 314 are optional.

Referring to FIG. 23A, in some embodiments, the metal fill layer 268 is disposed in the top gate region 408T and the bottom gate region 408B. The metal fill layer 268 may extend between the stacks of bottom semiconductor layers 2080T of the neighboring active regions 204 along the Y-direction. In such embodiments, the adhesion layer 266 has a thickness in a range between about 10 angstroms and about 25 angstroms. In the depicted embodiment, the interfacial layer 252, the gate dielectric layer 254, the second type WFM layer 260, the passivation layer 264, the adhesion layer 266, and the metal fill layer 268 in the top gate region 408T collectively form the top segment 250T of the gate structure 250. In the depicted embodiment, the interfacial layer 252, the gate dielectric layer 254, the first type WFM layer 258, the barrier layer 404, the second type WFM layer 260, the passivation layer 264, the adhesion layer 266, and the metal fill layer 268 in the bottom gate region 408B collectively form the bottom segment 250B of the gate structure 250.

Referring to FIG. 23B, in some alternative embodiments, the metal fill layer 268 is disposed in the top gate region 408T but not the bottom gate region 408B. This may be because of limited distance between neighboring active regions 204. In such embodiments, the adhesion layer 266 may have a thickness greater than about 25 angstroms. In such embodiments, the metal fill layer 268 is above and not disposed between the stacks of bottom semiconductor layers 2080T of the neighboring active regions 204 along the Y-direction. In the depicted embodiment, the interfacial layer 252, the gate dielectric layer 254, the second type WFM layer 260, the passivation layer 264, the adhesion layer 266, and the metal fill layer 268 in the top gate region 408T collectively form the top segment 250T of the gate structure 250. In the depicted embodiment, the interfacial layer 252, the gate dielectric layer 254, the first type WFM layer 258, the barrier layer 404, the second type WFM layer 260, the passivation layer 264, and the adhesion layer 266 in the bottom gate region 408B collectively form the bottom segment 250B of the gate structure 250.

A fragmentary cross-sectional view of the structure 400 taken along line A-A′ as in FIG. 2 is similar to FIG. 11. The structure 400 may include a top device 212T and a bottom device 212B. Although FIGS. 3-4, 11 and 17-23B illustrate stacked transistor structures having GAA transistors, other examples of semiconductor devices (e.g., multigate devices, stacked transistor structures having any combination of transistors, such as planar, FinFET, nanosheet, and nanowire transistors) may benefit from aspects of the present disclosure. Some examples of stacked transistor structures are provided as in FIGS. 15A-15C. The alternative structure 400 may undergo further processes similar as described above to the structure 200.

Referring back to FIG. 16, in some embodiments, instead of blocks 306 and 308, method 300 includes blocks 316 and 318. FIGS. 24-29B illustrate fragmentary cross-sectional views of an alternative structure 400′ at different stages of fabrication according to blocks 316 and 318 and other processes of method 300. Before block 316, the alternative structure 400′ may undergo the operations at blocks 302 and 304 similar as described above.

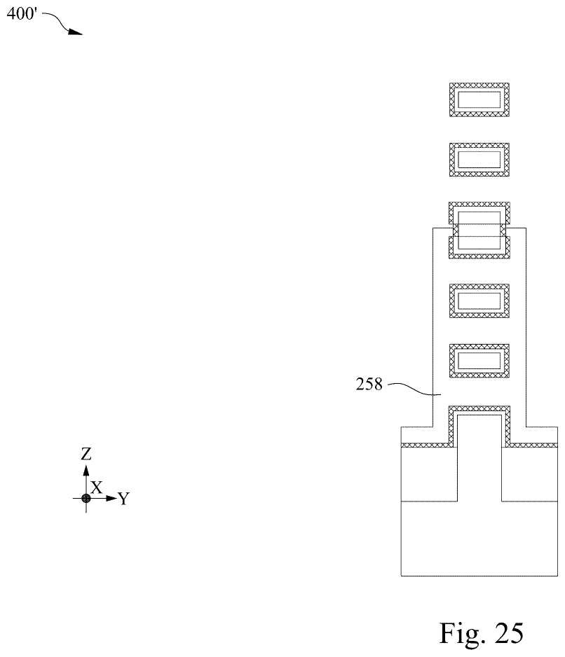

Referring to FIGS. 16 and 24-25, method 300 includes a block 316 where a top portion of the first type WFM layer 258 is removed from the top semiconductor layers 2080T. Operations at block 316 may include depositing a BARC layer 406′ over the first type WFM layer 258, etching back the BARC layer 406′ to expose the top portion of the first type WFM layer 258 (as in FIG. 24), etching back the top portion of the first type WFM layer 258 above the remaining BARC layer 406′, and removing the remaining BARC layer 406′ (as in FIG. 25).

The operations at block 316 may be similar to the operations at block 308. For example, depositing the BARC layer 406′, etching back the BARC layer 406′, and removing the remaining BARC layer 406′ may use similar methods as those described above with respect to the BARC layer 406 at block 308. The BARC layer 406′ may have a similar composition as the BARC layer 406 described above. A top surface of the remaining BARC layer 406′ after etching back the BARC layer 406′ may be at a level similar to that of the remaining BARC layer 406 described above. Etching back the top portion of the first type WFM layer 258 may use similar method as described above for etching back the top portions of the first type WFM layer 258 and the barrier layer 404 at block 308. Differences include that, at block 316, there is no barrier layer over the first type WFM layer 258, thus only the top portion of the first type WFM layer 258 is etched back. After etching back, a topmost surface of a remaining bottom portion of the first type WFM layer 258 may be the same as the remaining BARC layer 406′. Then, the remaining BARC layer 406′ is removed.

Referring to FIGS. 16 and 26-27, method 300 includes a block 318 where a gas treatment 410 is performed to the structure 400′, thereby forming a barrier layer 404′ over the bottom portion of the first type WFM layer 258. The gas treatment 410 may be performed in-situ with the operations at block 316. In some embodiments, removing the top portion of the first type WFM layer 258 and performing the gas treatment 410 are in a same chamber. The gas treatment 410 is similar to the gas treatment 262 or 402 described above, and composition and a thickness of the barrier layer 404′ are similar to those of the passivation layer 264 or the barrier layer 404. The barrier layer 404′ is disposed over top surfaces and sidewalls of the bottom portion of the first type WFM layer 258.

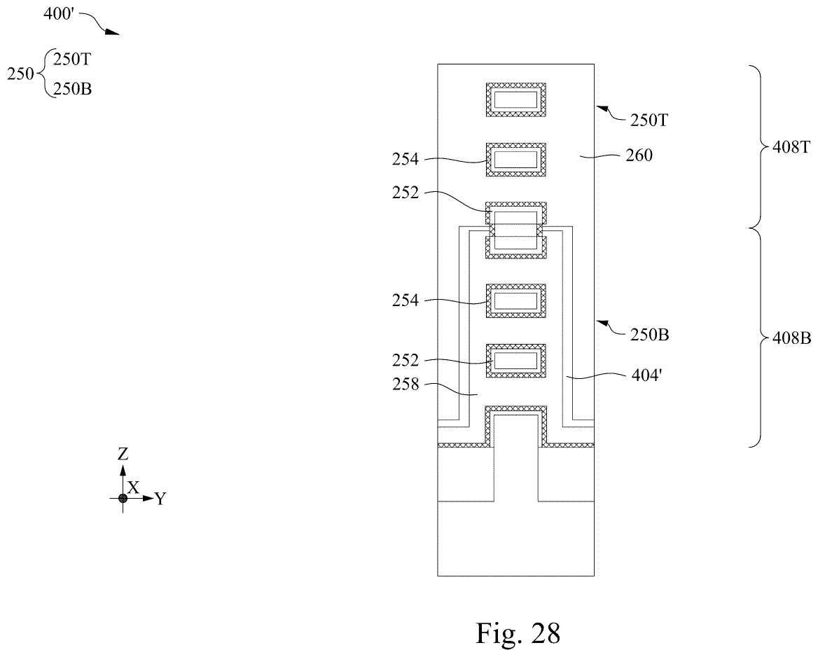

Referring to FIGS. 16 and 28, the structure 400′ then undergoes block 310 as described above. Compared to the structure 400 at block 310 as described above with respect to FIG. 22, differences include the follows. In the structure 400′, the barrier layer 404′ is further disposed on a topmost surface of the first type WFM layer 258. In some embodiments, the first type WFM layer 258 and the second type WFM layer 260 are completely separated by the barrier layer 404′. The top segment 250T of the gate structure 250 further includes a portion of the barrier layer 404′ on the topmost surface of the first type WFM layer 258.

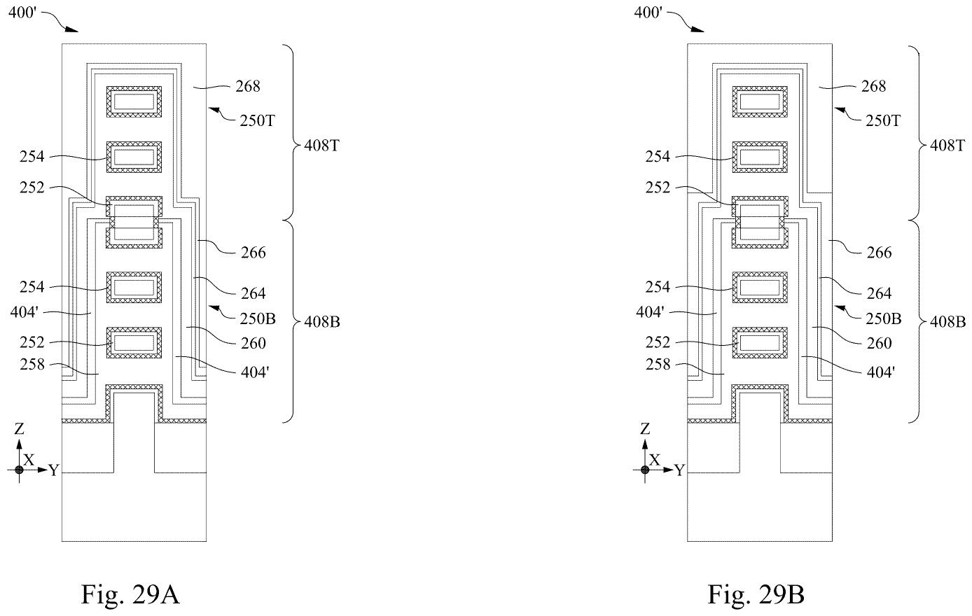

In some embodiments, the structure 400′ optionally undergoes blocks 312 and/or 314 as described above. Comparing the structure 400′ in FIGS. 29A-29B and the structure 400 in FIGS. 23A-23B, respectively, differences include the follows. In the structure 400′, the barrier layer 404′ is further disposed on the topmost surface of the structure 400′. In some embodiments, the first type WFM layer 258 and the second type WFM layer 260 are completely separated by the barrier layer 404′. The top segment 250T of the gate structure 250 further includes the portion of the barrier layer 404′ on the topmost surface of the first type WFM layer 258. The alternative structure 400′ may undergo further processes similar as described above to the structure 200.

Referring to FIG. 30, in some other embodiments, another alternative structure 400″ is manufactured according to method 300. Compared to the structure 400′ and the fabrication thereof described in FIGS. 24-28, differences include the follows. At block 304, instead of laterally extending in a portion of the trench 238, in the structure 400″, the first type WFM layer 258 is formed to extend fully between the neighboring active regions 204. At block 316, the top portion of the first type WFM 258 may be removed by any suitable method such as a selective etching process (e.g., a dry etch, a wet etch). In such embodiments, a BARC layer may not be used. At block 318, a barrier layer 404″ is formed on the topmost surface but not sidewalls of the first type WFM layer 258. The barrier layer 404″ may be formed using similar method as the barrier layer 404′ and have similar composition and thickness as the barrier layer 404′. At block 310, the second type WFM layer 260 is formed on the topmost surface but not sidewalls of the barrier layer 404″.

Referring to FIGS. 16 and 31A-31B, in some embodiments, the alternative structure 400″ undergoes operations at blocks 312 and 314 to form more layers over the second type WFM layer 260. Comparing the structure 400″ in FIGS. 31A-31B to the structure 400′ in FIGS. 29A and 29B, respectively, differences include the follows. In FIG. 31A, the barrier layer 404″, the second WFM layer 258, the passivation layer 264, the adhesion layer 266, and the metal fill layer 268 do not extend into the bottom gate region 408B. In FIG. 31B, the barrier layer 404″, the second WFM layer 258, the passivation layer 264, and the adhesion layer 266 do not extend into the bottom gate region 408B. The adhesion layer 266 and the metal fill layer 268 are formed over the second type WFM layer 260 similarly to that in FIGS. 10A and 10B, respectively. In FIGS. 31A-31B, the interfacial layer 252, the gate dielectric layer 254, and the first WFM layer 258 in the bottom gate region 408B collectively form the bottom segment 250B of the gate structure 250. In the structure 400″, the interfacial layer 252, the gate dielectric layer 254, the barrier layer 404″, the second WFM layer 258, the passivation layer 264, the adhesion layer 266, and the metal fill layer 268 in the top gate region 408T collectively form the top segment 250T of the gate structure 250. The alternative structure 400″ may undergo further processes similar as described above to the structure 200.

Although not intended to be limiting, one or more embodiments of the present disclosure provide many benefits to a semiconductor structure. For example, by performing a gas treatment, a passivation layer and/or a barrier layer including silicon and/or carbon is formed, which may mitigate oxygen diffusion and/or metal diffusion, thus reducing Vt shift and providing improved Vt control and Vt tuning method. Thus, the overall performance of the semiconductor device may be improved. The method of the present disclosure may be applied in fabricating any suitable structures, such as a CFET with a relatively high aspect ratio.

In one exemplary aspect, the present disclosure is directed to a method. The method includes providing a structure. The structure includes a stack of bottom channel layers, a stack of top channel layers disposed over the stack of bottom channel layers, an isolation feature sandwiched by the stack of bottom channel layers and the stack of bottom channel layers, and a first work function metal (WFM) layer wrapping around each of the bottom channel layers. The method further includes forming a second WFM layer wrapping around each of the top channel layers, forming a passivation layer on the second WFM layer by performing a gas treatment to the structure, and forming a metal fill layer over the passivation layer.

In some embodiments, the gas treatment includes performing a thermal soak process with a gas including a silicon-containing gas, a carbon-containing gas, or a combination thereof. In some embodiments, the gas treatment includes generating a silicon radical from a silicon-containing gas. In some embodiments, the first WFM layer includes a p-type WFM, and the second WFM layer includes an n-type WFM. In some embodiments, the passivation layer includes silicon oxide. In some embodiments, the gas treatment is a first gas treatment, and the method further includes performing a second gas treatment to the structure, thereby forming a barrier layer between the first WFM layer and the second WFM layer. In some embodiments, the method further includes forming an adhesion layer between the passivation layer and the metal fill layer. In some embodiments, performing the gas treatment to the structure is at a temperature lower than about 500 degree C.

In another exemplary aspect, the present disclosure is directed to a method. The method includes providing a structure. The structure includes a stack of bottom channel layers, an isolation feature disposed over the stack of bottom channel layers, a stack of top channel layers disposed over the isolation feature, and a first work function metal (WFM) layer wrapping around the stack of top channel layers and the stack of bottom channel layers. The method further includes performing a gas treatment to the structure, thereby forming a barrier layer over the first WFM layer, removing the first WFM layer from the stack of top channel layers, and forming a second WFM layer wrapping around the stack of top channel layers and over the first WFM layer and the barrier layer, such that the barrier layer is disposed between the first WFM layer and the second WFM layer.

In some embodiments, the gas treatment is a first gas treatment, and the method further includes performing a second gas treatment to the structure, thereby forming a passivation layer on the second WFM layer. In some embodiments, the barrier layer includes silicon oxide, metal carbide, or a combination thereof. In some embodiments, the gas treatment uses a silicon-based gas, a carbon-based gas, or a combination thereof. In some embodiments, performing the gas treatment to the structure is before removing the first WFM layer from the stack of top channel layers, and removing the first WFM layer from the stack of top channel layers includes removing a top portion of the barrier layer, such that a top surface of the first WFM layer is exposed. In some embodiments, performing the gas treatment to the structure is after removing the first WFM layer from the stack of top channel layers, and the barrier layer is disposed on a topmost surface and sidewalls of the first WFM layer. In some embodiments, the structure further includes an interfacial layer and a gate dielectric layer disposed between the top channel layers and the first WFM layer, after removing the first WFM layer from the stack of top channel layers, the gate dielectric layer over the top channel layers is exposed.

In yet another exemplary aspect, the present disclosure is directed to a semiconductor structure. The semiconductor structure includes a substrate, a bottom channel layer disposed over the substrate, a dielectric isolation feature disposed over the bottom channel layer, a top channel layer disposed over the dielectric isolation feature, a first work function metal (WFM) layer wrapping around the bottom channel layer, a second WFM layer wrapping around the top channel layer, and a barrier layer disposed on a sidewall of the second WFM layer. The barrier layer includes silicon oxide, metal carbide, or a combination thereof.

In some embodiments, the barrier layer is disposed between the first WFM layer and the second WFM layer, the semiconductor structure further includes a passivation layer disposed over the second WFM layer and a metal fill layer disposed over the passivation layer, the passivation layer includes silicon oxide, metal carbide, or a combination thereof. In some embodiments, a topmost surface of the first WFM layer is in direct contact with the second WFM layer, and sidewalls of the first WFM layer are spaced apart from the second WFM layer by the barrier layer. In some embodiments, top surfaces and sidewalls of the first WFM layer are spaced apart from the second WFM by the barrier layer. In some embodiments, the first WFM layer, the second WFM layer, and the barrier layer interface with the dielectric isolation feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
providing a structure comprising:
a stack of bottom channel layers,
a stack of top channel layers disposed over the stack of bottom channel layers,
an isolation feature sandwiched by the stack of bottom channel layers and the stack of bottom channel layers, and
a first work function metal (WFM) layer wrapping around each of the bottom channel layers;
forming a second WFM layer wrapping around each of the top channel layers;
forming a passivation layer on the second WFM layer by performing a gas treatment to the structure; and
forming a metal fill layer over the passivation layer.

2. The method of claim 1, wherein the gas treatment comprises performing a thermal soak process with a gas comprising a silicon-containing gas, a carbon-containing gas, or a combination thereof.

3. The method of claim 1, wherein the gas treatment comprises generating a silicon radical from a silicon-containing gas.

4. The method of claim 1, wherein the first WFM layer comprises a p-type WFM, and the second WFM layer comprises an n-type WFM.

5. The method of claim 1, wherein the passivation layer comprises silicon oxide.

6. The method of claim 1, wherein the gas treatment is a first gas treatment, and
wherein the method further comprises performing a second gas treatment to the structure, thereby forming a barrier layer between the first WFM layer and the second WFM layer.

7. The method of claim 1, further comprising forming an adhesion layer between the passivation layer and the metal fill layer.

8. The method of claim 1, wherein performing the gas treatment to the structure is at a temperature lower than about 500 degree C.

9. A method comprising:
providing a structure comprising:
a stack of bottom channel layers,
an isolation feature disposed over the stack of bottom channel layers,
a stack of top channel layers disposed over the isolation feature, and
a first work function metal (WFM) layer wrapping around the stack of top channel layers and the stack of bottom channel layers;
performing a gas treatment to the structure, thereby forming a barrier layer over the first WFM layer;
removing the first WFM layer from the stack of top channel layers; and
forming a second WFM layer wrapping around the stack of top channel layers and over the first WFM layer and the barrier layer, such that the barrier layer is disposed between the first WFM layer and the second WFM layer.

10. The method of claim 9, wherein the gas treatment is a first gas treatment, and
wherein the method further comprises performing a second gas treatment to the structure, thereby forming a passivation layer on the second WFM layer.

11. The method of claim 9, wherein the barrier layer comprises silicon oxide, metal carbide, or a combination thereof.

12. The method of claim 9, wherein the gas treatment uses a silicon-based gas, a carbon-based gas, or a combination thereof.

13. The method of claim 9, wherein performing the gas treatment to the structure is before removing the first WFM layer from the stack of top channel layers, and
wherein removing the first WFM layer from the stack of top channel layers comprises removing a top portion of the barrier layer, such that a top surface of the first WFM layer is exposed.

14. The method of claim 9, wherein performing the gas treatment to the structure is after removing the first WFM layer from the stack of top channel layers, and
wherein the barrier layer is disposed on a topmost surface and sidewalls of the first WFM layer.

15. The method of claim 9, wherein the structure further comprises an interfacial layer and a gate dielectric layer disposed between the top channel layers and the first WFM layer,
wherein after removing the first WFM layer from the stack of top channel layers, the gate dielectric layer over the top channel layers is exposed.

16. A semiconductor structure, comprising:
a substrate;
a bottom channel layer disposed over the substrate;
a dielectric isolation feature disposed over the bottom channel layer;
a top channel layer disposed over the dielectric isolation feature;
a first work function metal (WFM) layer wrapping around the bottom channel layer;
a second WFM layer wrapping around the top channel layer; and
a barrier layer disposed on a sidewall of the second WFM layer,
wherein the barrier layer comprises silicon oxide, metal carbide, or a combination thereof.

17. The semiconductor structure of claim 16, wherein the barrier layer is disposed between the first WFM layer and the second WFM layer,
wherein the semiconductor structure further comprises a passivation layer disposed over the second WFM layer and a metal fill layer disposed over the passivation layer,
wherein the passivation layer comprises silicon oxide, metal carbide, or a combination thereof.

18. The semiconductor structure of claim 16, wherein a topmost surface of the first WFM layer is in direct contact with the second WFM layer, and
wherein sidewalls of the first WFM layer are spaced apart from the second WFM layer by the barrier layer.

19. The semiconductor structure of claim 16, wherein top surfaces and sidewalls of the first WFM layer are spaced apart from the second WFM by the barrier layer.

20. The semiconductor structure of claim 16, wherein the first WFM layer, the second WFM layer, and the barrier layer interface with the dielectric isolation feature.
